(19) United States
(12) Patent Application Publication
(10) Pub. No.: US 2025/0279052 A1
(43) Pub. Date: Sep. 4, 2025

(54) SUB-PIXEL AND DISPLAY DEVICE INCLUDING THE SUB-PIXEL, AND ELECTRONIC DEVICE

(71) Applicant: Samsung Display Co., LTD., Yongin-si (KR)

(72) Inventors: Kyung Bae KIM, Yongin-si (KR); Jin Seon KWAK, Yongin-si (KR); Dong Woo KIM, Yongin-si (KR); Ji Hye LEE, Yongin-si (KR)

(21) Appl. No.: 18/991,628

(22) Filed: Dec. 22, 2024

(30) Foreign Application Priority Data
Mar. 4, 2024 (KR) 10-2024-0030701

(51) Int. Cl. G09G 3/3233; G09G 3/32; G09G 3/3266; G09G 3/3275

(52) U.S. Cl. CPC G09G 3/3233; G09G 3/32; G09G 3/3266; G09G 3/3275; G09G 2310/0267; G09G 2310/0275

(57) ABSTRACT

A sub-pixel includes: a first transistor including a first electrode connected to a first node, a second electrode connected to a second node, and a gate electrode connected to a third node; a second transistor that is connected between a data line and the third node, wherein a gate electrode of the second transistor is connected to a first sub-gate line; a first capacitor connected between the first node and the third node; and a second capacitor connected between the second node and the third node, wherein the first capacitor and the second capacitor are formed as different types of capacitors.

This application claims priority to Korean Patent Application No. 10-2024-0030701, filed on Mar. 4, 2024, and all the benefits accruing therefrom under 35 U.S.C. § 119, the content of which in its entirety is herein incorporated by reference.

### BACKGROUND

### (1) Field

The present disclosure relates to a sub-pixel and a display device including the sub-pixel, and electronic device.

### (2) Description of the Related Art

As information technology has developed, the importance of a display device, which is a connection medium between a user and information, has been highlighted. Accordingly, the use of display devices such as, for example, a liquid crystal display device, an organic light emitting display device, and the like has been increasing.

Recently, a head mounted display device (HMD) has been developed. A head mounted display device is a display device that a user may wear in the form of glasses or a helmet to implement virtual reality (VR) or augmented reality (AR) that focuses on a distance close to the eyes. High-resolution panels are applied to the head mounted display device, and accordingly, sub-pixels applicable to the high-resolution panels may be required.

### SUMMARY

An embodiment of the present disclosure provides a sub-pixel applicable to a high-resolution panel and a display device including the sub-pixel.

Embodiments of the present disclosure provide a sub-pixel including: a first transistor including a first electrode connected to a first node, a second electrode connected to a second node, and a gate electrode connected to a third node; a second transistor that is connected between a data line and the third node, wherein a gate electrode of the second transistor is connected to a first sub-gate line; a first capacitor connected between the first node and the third node; and a second capacitor connected between the second node and the third node, wherein the first capacitor and the second capacitor are formed as different types of capacitors.

The first capacitor may be a metal-oxide-semiconductor (MOS) capacitor, and the second capacitor may be a metal-oxide-metal (MOM) capacitor.

The first capacitor may have a higher capacity than the second capacitor.

The first capacitor may be formed on the same layer as the first transistor, and the second capacitor may be formed on a different layer from the first transistor.

The second capacitor may include a first electrode and a second electrode, and the first electrode may be formed on the same layer as the second electrode.

A mounting area of the first capacitor may be larger than a mounting area of the first transistor or a mounting area of the second transistor.

The sub-pixel may further include a third transistor that is connected between a first power voltage node to which a first power voltage is inputted and the first node, wherein a gate electrode of the third transistor is connected to a light emitting control line; a light emitting element connected between a second power voltage node to which a second power voltage is inputted and the second node; and a fourth transistor that is connected between the second node and an initialization voltage node to which an initialization voltage is supplied, wherein a gate electrode of the fourth transistor is connected to a second sub-gate line.

The initialization voltage may be the same voltage as the second power voltage, and the initialization voltage node may be electrically connected to the second power voltage node.

The initialization voltage may be set such that the light emitting element is turned off when supplied to the second node.

Each of the first transistor, the second transistor, the third transistor, and the fourth transistor may be a metal-oxide-semiconductor field-effect transistor (MOSFET) including a body electrode.

The first power voltage may be inputted to the body electrodes of the first transistor, the second transistor, the third transistor, and the fourth transistor.

The sub-pixel may be driven in a first period, a second period, and a third period, the second transistor may be turned on during the first period and the second period, the fourth transistor may be turned on during the first period to the third period, and the third transistor may be turned off during the second period.

A data signal may be supplied to the data line during at least a portion of the second period.

Another embodiment of the present disclosure provides a display device including: sub-pixels connected to gate lines, light emitting control lines, and data lines; a gate driver driving the gate lines and the light emitting control lines; and a data driver driving the data lines, wherein a sub-pixel of the sub-pixels includes a first transistor including a first electrode connected to a first node, a second electrode connected to a second node, and a gate electrode connected to a third node; a second transistor that is connected between a data line, which is one of the data lines, and the third node, wherein a gate electrode of the second transistor is connected to a first sub-gate line, which is one of the gate lines; a first capacitor connected between the first node and the third node; and a second capacitor connected between the second node and the third node, and the first capacitor and the second capacitor are formed as different types of capacitors.

The first capacitor may be a metal-oxide-semiconductor (MOS) capacitor, and the second capacitor may be a metal-oxide-metal (MOM) capacitor.

The first capacitor may have a higher capacity than the second capacitor.

The first capacitor may be formed on the same layer as the first transistor, and the second capacitor may be formed on a different layer from the first transistor.

The second capacitor may include a first electrode and a second electrode, and the first electrode may be formed on the same layer as the second electrode.

A mounting area of the first capacitor may be larger than a mounting area of the first transistor or a mounting area of the second transistor.

The sub-pixel may further include a third transistor that is connected between a first power voltage node to which a first power voltage is inputted and the first node, wherein a gate electrode of the third transistor is connected to one of the light emitting control lines; a light emitting element connected between a second power voltage node to which a second power voltage is inputted and the second node; and a fourth transistor that is connected between the second node and an initialization voltage node to which an initialization voltage is supplied, wherein a gate electrode of the fourth transistor is connected to a second sub-gate line that is one of the gate lines.

The initialization voltage may be the same voltage as the second power voltage, and the initialization voltage node may be electrically connected to the second power voltage node.

Each of the first transistor, the second transistor, the third transistor, and the fourth transistor may include a body electrode, and the first power voltage may be inputted to the body electrodes of the first transistor, the second transistor, the third transistor, and the fourth transistor.

The sub-pixel may be driven in a first period, a second period, and a third period, the gate driver may supply a first scan signal to the first sub-gate line such that the second transistor is turned on during the first period and the second period, the gate driver may supply a second scan signal to the second sub-gate line such that the fourth transistor is turned on during the first period to the third period, the gate driver may supply a light emitting control signal to the light emitting control line such that the third transistor is turned off during the second period, and the data driver may supply a data signal to the data line during at least a portion of the second period.

Another embodiment of the present disclosure provides an electronic device including: a processor to provide input image data; a display device to display an image based on the input image data. The display device including: sub-pixels connected to gate lines, light emitting control lines, and data lines; a gate driver driving the gate lines and the light emitting control lines; and a data driver driving the data lines, wherein a sub-pixel of the sub-pixels includes a first transistor including a first electrode connected to a first node, a second electrode connected to a second node, and a gate electrode connected to a third node; a second transistor that is connected between a data line, which is one of the data lines, and the third node, wherein a gate electrode of the second transistor is connected to a first sub-gate line, which is one of the gate lines; a first capacitor connected between the first node and the third node; and a second capacitor connected between the second node and the third node, and the first capacitor and the second capacitor are formed as different types of capacitors.

Objectives of the present disclosure are not limited to the objectives mentioned above, and other technical objectives that are not mentioned may be clearly understood to a person of an ordinary skill in the art using the following description.

The sub-pixel according to the embodiments of the present disclosure includes different types of capacitors, thereby shortening a process time and securing a sufficient capacity. In some aspects, the sub-pixels according to the embodiments of the present disclosure may be formed on a silicon substrate, and thus may be applied to a high-resolution panel.

However, the effects of the present disclosure are not limited to the above-described effects, and may be variously extended without departing from the spirit and scope of the present disclosure.

### BRIEF DESCRIPTION OF THE DRAWINGS

FIG. 1 illustrates a block diagram of an embodiment of a display device.

FIG. 2 illustrates a block diagram of one of sub-pixels of FIG. 1 according to an embodiment.

FIG. 3 illustrates an embodiment of a gate driver for driving the sub-pixel illustrated in FIG. 2.

FIG. 4 illustrates a circuit diagram of an embodiment of the sub-pixel of FIG. 2.

FIG. 5 illustrates a circuit diagram of an embodiment of the sub-pixel of FIG. 2.

FIG. 6 illustrates a waveform diagram of an embodiment of a driving method of the sub-pixel illustrated in FIG. 4.

FIG. 7A to FIG. 7D illustrate an embodiment of an operation process of a sub-pixel corresponding to a driving waveform of FIG. 6.

FIG. 8 illustrates a waveform diagram of an embodiment of a driving method of the sub-pixel illustrated in FIG. 4.

FIG. 9 illustrates a top plan view of an embodiment of a display panel of FIG. 1.

FIG. 10 illustrates an exploded perspective view of a portion of the display panel of FIG. 9.

FIG. 11 illustrates a top plan view of an example of one of pixels of FIG. 10.

FIG. 12 illustrates a cross-sectional view taken along line I-I′ of FIG. 11.

FIG. 13 schematically illustrates circuit elements disposed in a sub-pixel area.

FIG. 14 illustrates a cross-sectional view of an embodiment of a light emitting structure included in one of first to third light emitting elements of FIG. 12.

FIG. 15 illustrates a cross-sectional view of another embodiment of a light emitting structure included in one of first to third light emitting elements of FIG. 12.

FIG. 16 illustrates a top plan view of one of pixels of FIG. 10 according to another embodiment.

FIG. 17 illustrates a top plan view of one of pixels of FIG. 10 according to another embodiment.

FIG. 18 illustrates a block diagram of an embodiment of a display system.

FIG. 19 illustrates a perspective view of an application example of the display system of FIG. 18.

FIG. 20 illustrates a head-mounted display device worn on a user of FIG. 19.

### DETAILED DESCRIPTION

Hereinafter, example embodiments of the present disclosure will be described in detail with reference to the accompanying drawings. The following description provides a sufficient disclosure to enable the understanding of the operation of embodiments of the present disclosure, and any other disclosure is omitted to avoid obscuring the scope of example aspects of the present disclosure. In some aspects, the inventive concept may be embodied in different forms and is not limited to the embodiments set forth herein. The embodiments described herein are provided for the purpose of describing technical concepts in sufficient detail for those skilled in the art to easily practice the same.

Throughout the specification, when it is described that an element is “connected” to another element, this includes the element not only being “directly connected”, but also being “indirectly connected” with another device in between. The terms used herein are for the purpose of describing specific embodiments and are not intended to limit the scope of example aspects of the present disclosure. Throughout the specification, unless explicitly described to the contrary, the word “comprise” and variations such as, for example, “comprises” or “comprising” will be understood to imply the inclusion of stated elements but not the exclusion of any other elements. For the purposes of this disclosure, “at least one of X, Y, and Z,” “at least one of X, Y, or Z,” and “at least one selected from the group consisting of X, Y, and Z” may be construed as X only, Y only, Z only, or any combination of two or more of X, Y, and Z, such as, for instance, XYZ, XYY, YZ, and ZZ. As used herein, the term “and/or” includes any and all combinations of one or more of the associated listed items.

Although the terms first, second, and the like may be used herein to describe various constituent elements, these constituent elements should not be limited by these terms. These terms are used to distinguish one constituent element from another. Thus, a first constituent element discussed below could be termed a second constituent element without departing from the teachings of the present disclosure.

Spatially relative terms, such as, for example, “beneath,” “below,” “lower,” “above,” “upper,” and the like, may be used herein for descriptive purposes, and, thereby, to describe one element or feature's relationship to another element(s) or feature(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the term “below” can encompass both an orientation of above and below. Furthermore, the apparatus may be otherwise oriented (for example, rotated 90 degrees or at other orientations), and, as such, the spatially relative descriptors used herein interpreted accordingly.

The term “substantially,” as used herein, means approximately or actually. The term “substantially equal” means approximately or actually equal. The term “substantially the same” means approximately or actually the same. The term “substantially perpendicular” means approximately or actually perpendicular. The term “substantially parallel” means approximately or actually parallel.

Various embodiments are described herein with reference to sectional illustrations that are schematic illustrations of example embodiments. As such, variations from the shapes of the illustrations as a result, for example, of manufacturing techniques and/or tolerances, are to be expected. Thus, embodiments disclosed herein should not be construed as limited to the particular illustrated shapes of areas, but are to include deviations in shapes that result from, for instance, manufacturing. Thus, the areas illustrated in the drawings are schematic in nature and their shapes are not intended to illustrate the actual shape of an area of a device and are not intended to be limiting.

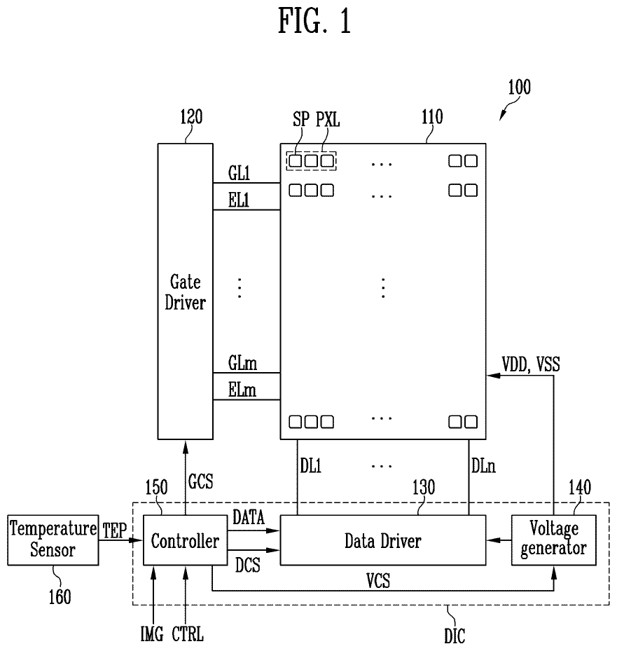

FIG. 1 illustrates a block diagram of an embodiment of a display device.

Referring to FIG. 1, a display device 100 may include a display panel 110, a gate driver 120, a data driver 130, a voltage generator 140, and a controller 150.

The display panel 110 includes sub-pixels SP. The sub-pixels SP may be connected to the gate driver 120 through first to m-th gate lines GL1 to GLm. The sub-pixels SP may be connected to the data driver 130 through first to n-th data lines DL1 to DLn. Each of the sub-pixels SP may include at least one light emitting element configured to generate light. Accordingly, the sub-pixels SP may respectively generate light of a specific color, such as, for example, red, green, blue, cyan, magenta, yellow, or the like. Two or more of the sub-pixels SP may configure one pixel PXL. For example, as illustrated in FIG. 1, three sub-pixels may configure one pixel PXL.

The gate driver 120 is connected to the sub-pixels SP arranged in a row direction through the first to m-th gate lines GL1 to GLm. The gate driver 120 may output scan signals to the first to m-th gate lines GL1 to GLm in response to a gate control signal GCS. In embodiments, the gate control signal GCS may include a start signal indicating the start of each frame, a horizontal synchronization signal for outputting scan signals in synchronization with the timing at which data signals are applied, and the like.

In some embodiments, first to m-th light emitting control lines EL1 to ELm connected to the sub-pixels SP in a row direction may be further provided. In this case, the gate driver 120 may include an emission driver configured to control the first to m-th light emitting control lines EL1 to ELm, and the emission driver may operate under the control of the controller 150.

The gate driver 120 may be disposed on one side of the display panel 110. However, embodiments are not limited thereto. For example, the gate driver 120 may be divided into two or more physically and/or logically separated drivers, and the drivers may be disposed on one side of the display panel 110 and the other side of the display panel 110 opposite to the one side. As described herein, the gate driver 120 may be disposed around the display panel 110 in various forms according to the embodiments.

The data driver 130 is connected to the sub-pixels SP arranged in a column direction through the first to n-th data lines DL1 to DLn. The data driver 130 receives image data (DATA) and data control signal DCS from the controller 150. The data driver 130 operates in response to the data control signal DCS. In embodiments, the data control signal DCS may include a source start pulse, a source shift clock, a source output enable signal, and the like.

The data driver 130 may use voltages from the voltage generator 140 to apply data signals having grayscale voltages corresponding to the image data (DATA) to the first to n-th data lines DL1 to DLn. In an example in which a scan signal is applied to each of the first to m-th gate lines GL1 to GLm, data signals corresponding to the image data DATA may be applied to the data lines DL1 to DLn. Accordingly, the corresponding sub-pixels SP may generate light corresponding to the data signals. Accordingly, an image is displayed on the display panel 110.

In some embodiments, the gate driver 120 and the data driver 130 may include complementary metal-oxide semiconductor (CMOS) circuit elements.

The voltage generator 140 may operate in response to a voltage control signal VCS from the controller 150. The voltage generator 140 is configured to generate a plurality of voltages and provide the generated voltages to constituent elements of the display device 100. For example, the voltage generator 140 may be configured to generate a plurality of voltages by receiving an input voltage from the outside of the display device 100, adjusting the received voltage, and regulating the adjusted voltage.

The voltage generator 140 may generate a first power voltage VDD and a second power voltage VSS, and the generated first and second power voltages VDD and VSS may be provided to the sub-pixels SP. The first power voltage VDD may have a relatively high voltage level, and the second power voltage VSS may have a voltage level lower than the first power voltage VDD. In other embodiments, the first power voltage VDD or the second power voltage VSS may be provided by an external device of the display device 100.

In some aspects, the voltage generator 140 may generate various voltages. For example, the voltage generator 140 may generate an initialization voltage applied to the sub-pixels SP. For example, during a sensing operation to sense electrical characteristics of transistors and/or light emitting elements of the sub-pixels SP, a predetermined reference voltage may be applied to the first to n-th data lines DL1 to DLn, and the voltage generator 140 may generate the reference voltage.

The controller 150 controls various operations of the display device 100. The controller 150 receives input image data IMG and a control signal CTRL for controlling the display of the input image data, from the outside. The controller 150 may provide the gate control signal GCS, the data control signal DCS, and the voltage control signal VCS in response to the control signal CTRL.

The controller 150 may convert the input image data IMG to be suitable for the display device 100 or the display panel 110 to output the image data DATA. In embodiments, the controller 150 may output the image data DATA by aligning the input image data IMG to be suitable for the sub-pixels SP of a row unit.

Two or more components of the data driver 130, the voltage generator 140, and the controller 150 may be mounted on one integrated circuit. As illustrated in FIG. 1, the data driver 130, the voltage generator 140, and the controller 150 may be included in a driver integrated circuit DIC. In this case, the data driver 130, the voltage generator 140, and the controller 150 may be functionally separate components within one driver integrated circuit DIC. In other embodiments, at least one of the data driver 130, the voltage generator 140, and the controller 150 may be provided as a component separated from the driver integrated circuit DIC.

The display device 100 may include at least one temperature sensor 160. The temperature sensor 160 is configured to sense a surrounding temperature and generate temperature data TEP representing the sensed temperature. In embodiments, the temperature sensor 160 may be disposed adjacent to the display panel 110 and/or the driver integrated circuit DIC.

The controller 150 may control various operations of the display device 100 in response to the temperature data TEP. In embodiments, the controller 150 may adjust the luminance of an image outputted from the display panel 110 in response to the temperature data TEP. For example, the controller 150 may control the data signals and the first and second power voltages VDD and VSS by controlling components such as, for example, the data driver 130 and/or the voltage generator 140.

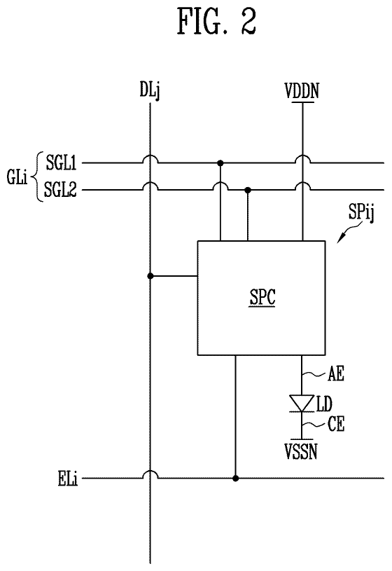

FIG. 2 illustrates a block diagram of one of sub-pixels of FIG. 1 according to an embodiment. In FIG. 2, among the sub-pixels SP of FIG. 1, a sub-pixel SPij disposed in an i-th row (i is an integer greater than or equal to 1 and less than or equal to m) and a j-th column (j is an integer greater than or equal to 1 and less than or equal to n) is illustrated as an example.

Referring to FIG. 2, the sub-pixel SPij may include a sub-pixel circuit SPC and a light emitting element LD.

The light emitting element LD is connected between the first power voltage node VDDN and a second power voltage node VSSN. In this case, the first power voltage node VDDN is a node that transmits the first power voltage VDD of FIG. 1, and the second power voltage node VSSN is a node that transmits the second power voltage VSS of FIG. 1.

An anode electrode AE of the light emitting element LD may be connected to the first power voltage node VDDN through the sub-pixel circuit SPC, and a cathode electrode CE of the light emitting element LD may be connected to the second power voltage node VSSN. For example, the anode electrode AE of the light emitting element LD may be connected to the first power voltage node VDDN through one or more transistors included in the sub-pixel circuit SPC.

The sub-pixel circuit SPC may be connected to an i-th gate line GLi among the first to m-th gate lines GL1 to GLm of FIG. 1, an i-th light emitting control line ELi among the first to m-th light emitting control lines EL1 to ELm of FIG. 1, and a j-th data line DLj among the first to n-th data lines DL1 to DLn of FIG. 1. The sub-pixel circuit SPC is configured to control the light emitting element LD according to signals received through these signal lines.

The sub-pixel circuit SPC may operate in response to a scan signal received through the i-th gate line GLi. The i-th gate line GLi may include one or more sub-gate lines. In the embodiments, as illustrated in FIG. 2, the i-th gate line GLi may include first and second sub-gate lines SGL1 and SGL2. The sub-pixel circuit SPC may operate in response to scan signals received through the first and second sub-gate lines SGL1 and SGL2. As such, when the i-th gate line GLi includes two or more sub-gate lines, the sub-pixel circuit SPC may operate in response to scan signals received through the corresponding sub-gate lines.

The sub-pixel circuit SPC may operate in response to a light emitting control signal received through the i-th light emitting control line ELi. In the embodiments, the i-th light emitting control line ELi may include one or more sub-light emitting control lines. In an example in which the i-th light emitting control line ELi includes two or more sub-light emitting control lines, the sub-pixel circuit SPC may operate in response to light emitting control signals received through the corresponding sub-light emitting control lines.

The sub-pixel circuit SPC may receive a data signal through the j-th data line DLj. The sub-pixel circuit SPC may store a voltage corresponding to the data signal in response to at least one of the scan signals received through the first and second sub-gate lines SGL1 and SGL2. In response to the light emitting control signal received through the i-th light emitting control line ELi, the sub-pixel circuit SPC may adjust the current flowing from the first power voltage node VDDN to the second power voltage node VSSN through the light emitting element LD according to the stored voltage. Accordingly, the light emitting element LD may generate light of luminance corresponding to the data signal.

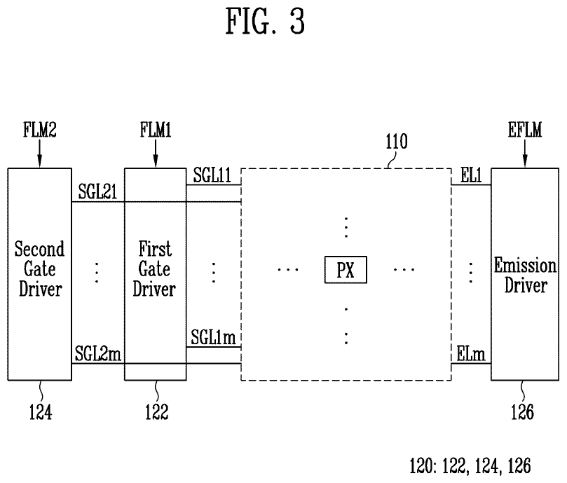

FIG. 3 illustrates an embodiment of a gate driver for driving the sub-pixel illustrated in FIG. 2. The gate control signal GCS may include a first scan start signal FLM1, a second scan start signal FLM2, and a light emitting start signal EFLM. In some aspects, the gate control signal GCS may include clock signals.

Referring to FIG. 3, the gate driver 120 may include a first gate driver 122, a second gate driver 124, and an emission driver 126.

The first gate driver 122 may receive the first scan start signal FLM1 and generate the first scan signal while shifting the first scan start signal FLM1 in response to the clock signal. The first gate driver 122 may sequentially supply the first scan signal to the first sub-gate lines SGL11 to SGL1m.

The second gate driver 124 may receive the second scan start signal FLM2 and generate the second scan signal while shifting the second scan start signal FLM2 in response to the clock signal. The second gate driver 124 may sequentially supply the second scan signal to the second sub-gate lines SGL21 to SGL2m.

The first scan signal (or enable first scan signal) and the second scan signal (or enable second scan signal) may be set to a gate-on voltage such that transistors included in the sub-pixels SP may be turned on.

For example, a first scan signal and a second scan signal having a logic low level may be supplied to a P-type transistor, and a first scan signal and a second scan signal having a logic high level may be supplied to an N-type transistor. The transistor to which the first scan signal or the second scan signal is supplied may be turned on in response to the first scan signal or the second scan signal. Thereafter, the supplying of the first scan signal and the second scan signal may mean that the gate-on voltage is supplied to the sub-gate lines SGL11 to SGL1m and SGL21 to SGL2m.

In some aspects, the first sub-gate line SGL1 illustrated in FIG. 2 may be one of the first sub-gate lines SGL11 to SGL1m. The second sub-gate line SGL2 illustrated in FIG. 2 may be one of the second sub-gate lines SGL21 to SGL2m.

The emission driver 126 may generate a light emitting control signal while shifting the light emitting start signal EFLM in response to the clock signal. The emission driver 126 may sequentially supply the light emitting control signal to the light emitting control lines EL1 to ELm. The light emitting control signal (or disabled light emitting control signal) may be set to a gate-off voltage such that the transistors included in the sub-pixels SP may be turned off.

For example, a logic high-level light emitting control signal may be supplied to the P-type transistor, and a logic low-level light emitting control signal may be supplied to the N-type transistor. A transistor receiving the light emitting control signal may be turned off in response to the light emitting control signal. Thereafter, supplying the light emitting control signal may mean that the gate-off voltage is supplied to the light emitting control lines EL1 to ELm.

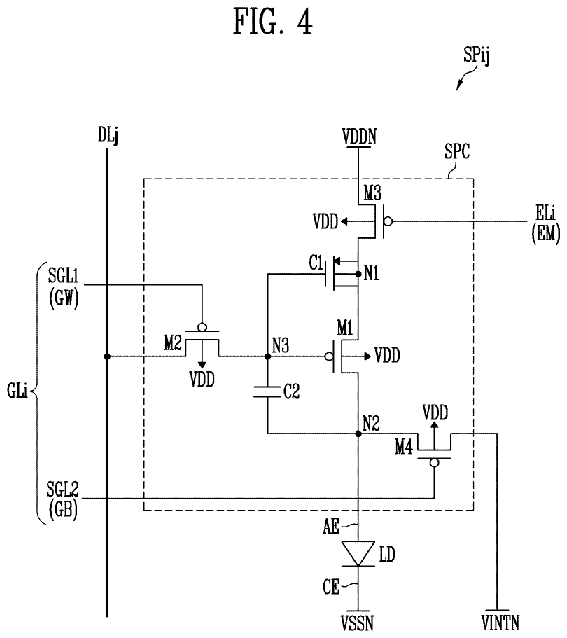

FIG. 4 illustrates a circuit diagram of an embodiment of the sub-pixel of FIG. 2.

Referring to FIG. 4, the sub-pixel SPij may include a sub-pixel circuit SPC and a light emitting element LD.

The light emitting element LD may include the anode electrode AE, the cathode electrode CE, and the light emitting layer. The light emitting layer may be disposed between the anode electrode AE and the cathode electrode CE. An anode electrode AE of the light emitting element LD may be electrically connected to the first power voltage node VDDN via a second node N2, a first transistor M1, a first node N1, and a third transistor M3, and a cathode electrode CE of the light emitting element LD may be electrically connected to the second power voltage node VSSN. The light emitting element LD may generate light with a predetermined luminance in response to the amount of current supplied from the first power voltage node VDDN to the second power voltage node VSSN via the sub-pixel circuit SPC.

The light emitting element LD may be selected as an organic light emitting diode. In some aspects, the light emitting element LD may be selected as an inorganic light emitting diode such as, for example, a micro light emitting diode (LED) or a quantum dot light emitting diode. In some aspects, the light emitting element LD may be an element in which an organic material and an inorganic material are complexly formed. In FIG. 4, it is illustrated that the pixel PXij includes a single light emitting element LD, but in another embodiment, the pixel PXij may include a plurality of light emitting elements LD, and the plurality of light emitting elements LD may be connected in series, in parallel or in series/parallel to each other.

The sub-pixel circuit SPC may include the first transistor M1, a second transistor M2, the third transistor M3, a fourth transistor M4, a first capacitor C1, and a second capacitor C2.

The first transistor M1 to the fourth transistor M4 may each be a metal-oxide-semiconductor field-effect transistor (MOSFET) including a body electrode. In this case, the first transistor M1 to the fourth transistor M4 may be mounted in a narrow area, and accordingly, the pixel PXij may be applied to a high resolution panel. The body electrodes of the first to fourth transistors M1 to M4 may be supplied with the first power voltage VDD.

In the embodiment, the first to fourth transistors M1 to M4 may be formed as P-type transistors. However, this is an example, and at least one of the first to fourth transistors M1 to M4 may be replaced with an N-type transistor.

The first electrode of the first transistor M1 may be connected to the first node N1, and the second electrode may be connected to the second node N2. Here, “connected” includes the meaning of being electrically connected. A gate electrode of the first transistor M1 may be connected to a third node N3. The first node N1 may mean a node to which a second electrode of the third transistor M3 is connected, and the second node N2 may mean a node to which the anode electrode AE of the light emitting element LD is connected. The first transistor M1 may control the amount of current supplied from the first power voltage node VDDN to the second power voltage node VSSN via the light emitting element LD in response to the voltage of the third node N3.

The second transistor M2 may be connected between the data line DLj and the third node N3. In some aspects, a gate electrode of the second transistor M2 may be electrically connected to the first sub-gate line SGL1. The second transistor M2 may be turned on when the first scan signal GW is supplied to the first sub-gate line SGL1 to electrically connect the data line DLj and the third node N3.

A first electrode of the third transistor M3 may be electrically connected to the first power voltage node VDDN, and the second electrode of the third transistor M3 may be connected to the first node N1. In some aspects, a gate electrode of the third transistor M3 may be electrically connected to the light emitting control line ELi. The third transistor M3 may be turned off when a light emitting control signal is supplied to the light emitting control line ELi (or when a disable light emitting control signal is supplied), and the third transistor M3 may be turned on when a light emitting control signal is not supplied (or when an enable light emitting control signal is supplied). In an example in which the third transistor M3 is turned off, the first power voltage node VDDN and the first node N1 may be electrically blocked.

A first electrode of the fourth transistor M4 may be connected to the second node N2, and a second electrode of the fourth transistor M4 may be electrically connected to the initialization voltage node VINTN. The initialization voltage node VINTN may be configured to transmit an initialization voltage. The initialization voltage may be provided by the voltage generator 140 of FIG. 1. The voltage generator 140 may set the initialization voltage to a voltage at which the light emitting element LD turns off when supplied to the anode electrode AE of the light emitting element LD. In an example in which the second scan signal GB is supplied to the second sub-gate line SGL2, the fourth transistor M4 may be turned on and electrically connect the second node N2 and the initialization voltage node VINTN.

The first capacitor C1 may be connected between the first node N1 and the third node N3. The first capacitor C1 may be formed as a metal-oxide-semiconductor (MOS) capacitor. The first capacitor C1 may be driven as a coupling capacitor, and may transmit the voltage change amount of the first node N1 to the third node N3. In some aspects, the first capacitor C1 may store the voltage of the third node N3.

A first electrode of the second capacitor C2 may be connected to the third node N3, and a second electrode of the second capacitor C2 may be connected to the second node N2. The second capacitor C2 may be formed as a different type of capacitor from the first capacitor C1. For example, the second capacitor C2 may be formed as a metal-oxide-metal (MOM) capacitor. The second capacitor C2 may be driven as a coupling capacitor, and may transmit the voltage change amount of the second node N2 to the third node N3. The second capacitor C2 may have a lower capacity than the first capacitor C1.

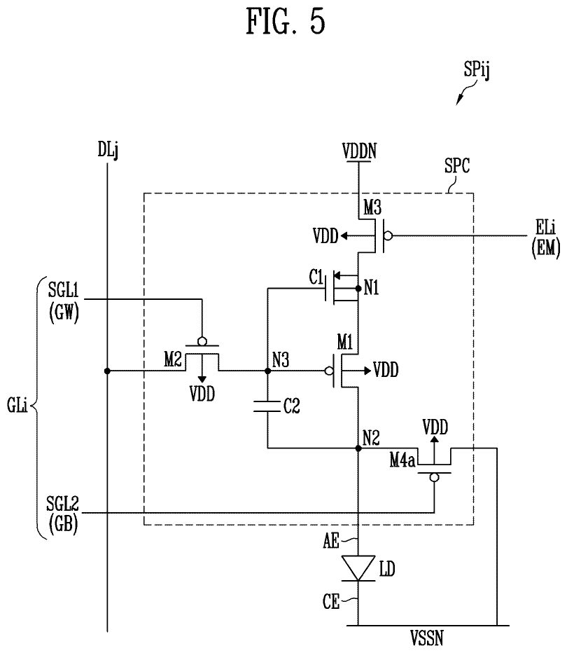

FIG. 5 illustrates a circuit diagram of an embodiment of the sub-pixel of FIG. 2. In describing FIG. 5, the same reference numerals are assigned to the same elements as those of FIG. 4, and redundant descriptions will be omitted.

Referring to FIG. 5, the sub-pixel circuit SPC may include the first transistor M1, the second transistor M2, the third transistor M3, a fourth transistor M4a, the first capacitor C1, and the second capacitor C2.

A first electrode of the fourth transistor M4a may be connected to the second node N2, and a second electrode of the fourth transistor M4a may be electrically connected to the second power voltage node VSSN. In an example in which the second scan signal GB is supplied to the second sub-gate line SGL2, the fourth transistor M4a may be turned on and electrically connect the second node N2 to the second power voltage node VSSN.

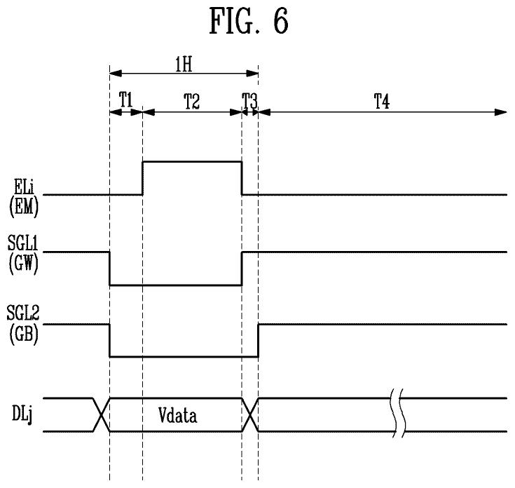

FIG. 6 illustrates a waveform diagram of an embodiment of a driving method of the sub-pixel illustrated in FIG. 4.

Referring to FIG. 6, a horizontal period 1H (or a specific horizontal period) in which the sub-pixel SPij is driven may be divided into a first period T1, a second period T2, and a third period T3.

The data driver 130 may supply the voltage Vdata of the data signal to the data line DLj during the first to third periods T1 to T3.

The gate driver 120 (or the first gate driver 122) may supply the first scan signal GW to the first sub-gate line SGL1 during the first period T1 and the second period T2.

The gate driver 120 (or the second gate driver 124) may supply the second scan signal GB to the second sub-gate line SGL2 during the first to third periods T1 to T3.

The gate driver 120 (or the light emission driver 126) may supply the light emitting control signal EM during the second period T2.

The first period T1 is a period in which the first power voltage VDD is supplied to the first node N1, the initialization voltage is supplied to the second node N2, and the voltage Vdata of the data signal is supplied to the third node N3. During the first period T1, the light emitting element LD may be initialized. During the first period T1, the first capacitor C1 and the second capacitor C2 may be initialized. The first period T1 may be referred to as an initialization period.

The second period T2 is a period in which the initialization voltage is supplied to the second node N2 and the voltage Vdata of the data signal is supplied to the third node N3. During the second period T2, a voltage corresponding to the threshold voltage of the first transistor M1 may be stored in the first capacitor C1. The second period T2 may be referred to as a data writing/threshold voltage compensation period.

During the third period T3, the first transistor M1 may control the amount of current supplied from the first power voltage VDD to the initialization voltage in response to the voltage of the third node N3. In this case, embodiments of the present disclosure support preventing an unnecessary current from being supplied to the light emitting element LD after the second period T2. The third period T3 may be referred to as a luminance control period.

During the fourth period T4, the first transistor M1 may control the amount of current supplied from the first power voltage node VDDN to the second power voltage node VSSN via the light emitting element LD in response to the voltage of the third node N3. During the fourth period T4, the light emitting element LD may emit light with a luminance corresponding to the amount of current supplied from the first transistor M1. The fourth period T4 may be referred to as a light emitting period.

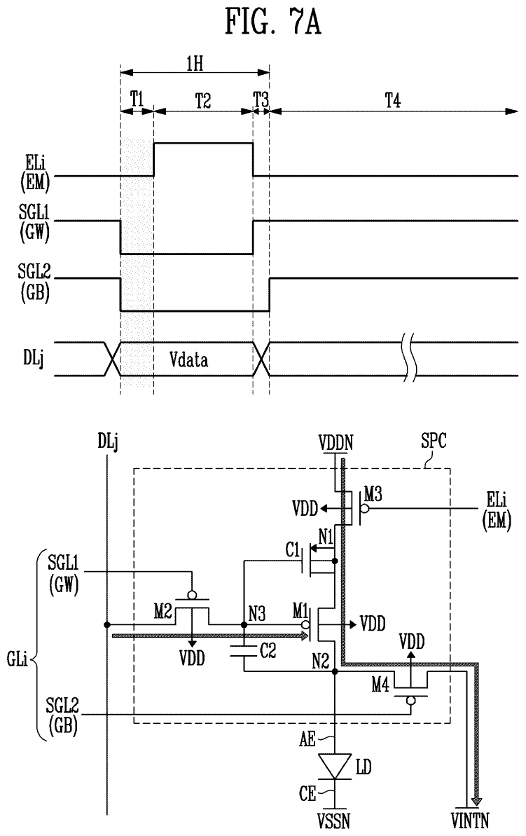

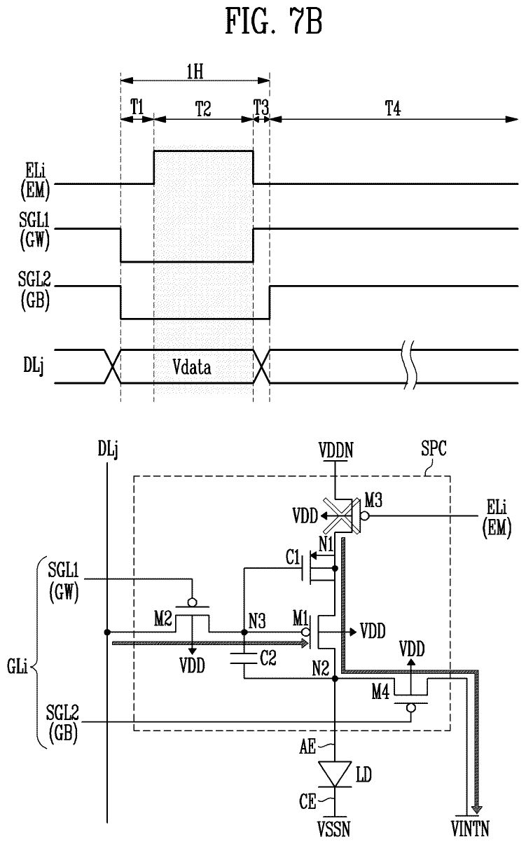

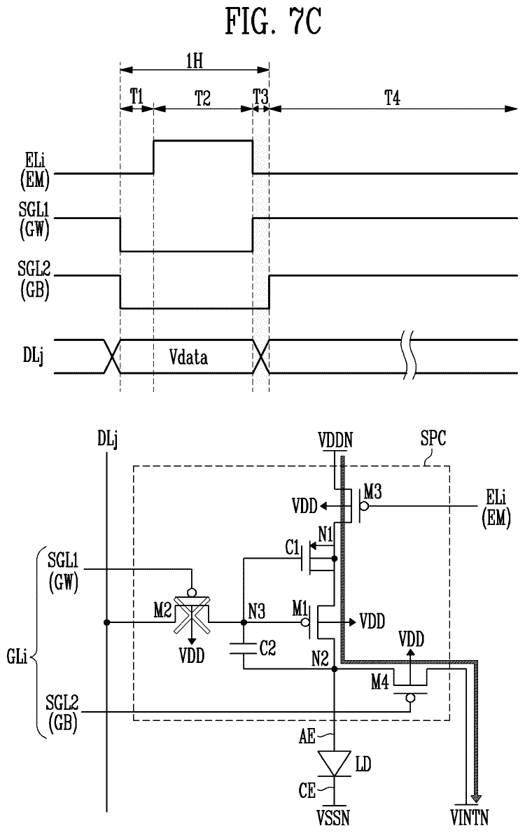

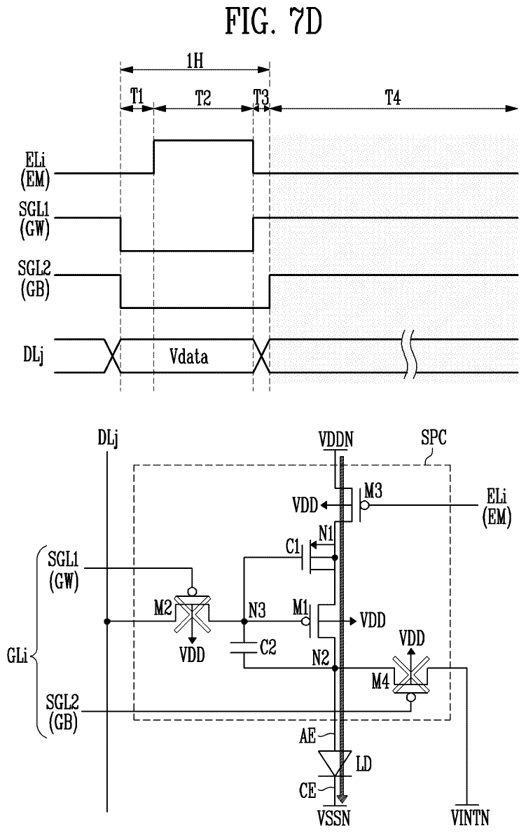

FIG. 7A to FIG. 7D illustrate an embodiment of an operation process of a sub-pixel corresponding to a driving waveform of FIG. 6.

Referring to FIG. 7A, during the first period T1, the first scan signal GW is supplied to the first sub-gate line SGL1, and the second scan signal GB is supplied to the second sub-gate line SGL2. In some aspects, during the first period T1, the light emitting control signal EM is not supplied to the light emitting control line ELi (or enable light emitting control is supplied), and accordingly, the third transistor M3 is set to the turned-on state. In an example in which the third transistor M3 is set to the turned-on state, the first power voltage VDD may be supplied to the first node N1.

When the first scan signal GW is supplied to the first sub-gate line SGL1, the second transistor M2 is turned on. In an example in which the second transistor M2 is turned on, the voltage Vdata of the data signal is supplied from the data line DLj to the third node N3. In this case, the first capacitor C1 may be initialized by the voltage Vdata of the data signal and the first power voltage VDD. For example, the first capacitor C1 may charge a voltage corresponding to the voltage Vdata of the data signal and the first power voltage VDD during the first period T1 regardless of the voltage charged in the previous period (or the previous frame period).

When the second scan signal GB is supplied to the second sub-gate line SGL2, the fourth transistor M4 is turned on. In an example in which the fourth transistor M4 is turned on, the initialization voltage is supplied to the second node N2. In an example in which the initialization voltage is supplied to the second node N2, the light emitting element LD may be initialized. In an example in which the initialization voltage is supplied to the second node N2, the parasitic capacitor (not illustrated) of the light emitting element LD may be discharged.

The second capacitor C2 may be initialized by the voltage Vdata of the data signal supplied to the third node N3 and the initialization voltage supplied to the second node N2. For example, the second capacitor C2 may charge a voltage corresponding to the voltage Vdata of the data signal and the initialization voltage during the first period T1 regardless of the voltage charged in the previous period (or the previous frame period).

During the first period T1, the current supplied from the first transistor M1 may be supplied to the initialization voltage node VINTN via the fourth transistor M4. Accordingly, the light emitting element LD may maintain a non-light emitting state during the first period T1.

Referring to FIG. 7B, during the second period T2, the second transistor M2 is maintained in the turned-on state by the first scan signal GW supplied to the first sub-gate line SGL1, and the fourth transistor M4 may be maintained in the turned-on state by the second scan signal GB supplied to the second sub-gate line SGL2.

In some aspects, the third transistor M3 may be turned off by the light emitting control signal EM supplied to the light emitting control line ELi during the second period T2. In an example in which the third transistor M3 is turned off, the first power voltage node VDDN and the first node N1 may be electrically blocked.

Since the second transistor M2 is set to the turned-on state during the second period T2, the voltage Vdata of the data signal is supplied from the data line DLj to the third node N3. In this case, the voltage of the first node N1 may fall from the first power voltage VDD to a voltage (Vdata+|Vth (M1) |) obtained by adding the absolute threshold voltage of the first transistor M1 to the voltage Vdata of the data signal.

That is, during the second period T2, the third node N3 may be set to the voltage Vdata of the data signal, and the first node N1 may be set to a voltage (Vdata+|Vth (M1) |) obtained by adding the absolute threshold voltage of the first transistor M1 to the voltage Vdata of the data signal. Accordingly, during the second period T2, the threshold voltage of the first transistor M1 may be stored in the first capacitor C1.

Since the fourth transistor M4 is set to the turned-on state during the second period T2, the current supplied from the first node N1 to the second node N2 via the first transistor M1 may be supplied to the initialization voltage node VINTN via the fourth transistor M4. Accordingly, the light emitting element LD may maintain a non-light emitting state during the second period T2.

Referring to FIG. 7C, the supply of the light emitting control signal EM to the light emitting control line ELi is stopped during the third period T3, and accordingly, the third transistor M3 may be set to the turned-on state. During the third period T3, the supply of the first scan signal GW to the first sub-gate line SGL1 is stopped, and accordingly, the second transistor M2 may be set to the turned-off state. During the third period T3, the second scan signal GB is supplied to the second sub-gate line SGL2, and accordingly, the fourth transistor M4 maintains the turned-on state.

Since the third transistor M3 is set to the turned-on state during the third period T3, the first transistor M1 controls the amount of current supplied from the first power voltage VDD to the second node N2 in response to the voltage applied to the third node N3. In this case, since the fourth transistor M4 is set to the turned-on state, the current supplied to the second node N2 may be supplied to the initialization voltage node VINTN. That is, during the third period T3, the light emitting element LD is set to the non-light emitting state, and accordingly, the grayscale expression of the display device 100 may be improved.

In detail, the voltage of the second node N2 may rise to a voltage higher than a desired voltage through the second period T2, and accordingly, an unnecessary current may be supplied to the light emitting element LD. For example, even when a black grayscale is implemented in the sub-pixel SPij, the light emitting element LD may temporarily emit light. Accordingly, in the embodiment of the present disclosure, the current supplied from the first transistor M1 during the third period T3 is supplied to the initialization power source Vint, and accordingly, the grayscale expression of the display device 100 may be improved.

In some aspects, when the grayscale is stably implemented in the display device 100, the third period T3 may be omitted.

Referring to FIG. 7D, the supply of the second scan signal GB to the second sub-gate line SGL2 is stopped during the fourth period T4, and accordingly, the fourth transistor M4 may be turned off. During the fourth period T4, the first scan signal GW is not supplied to the first sub-gate line SGL1, and accordingly, the second transistor M2 maintains the turned-off state. During the fourth period T4, the light emitting control signal EM is not supplied to the light emitting control line ELi, and accordingly, the third transistor M3 may maintain the turned-on state.

In this case, the first transistor M1 controls the amount of current supplied from the first power voltage node VDDN to the second power voltage node VSSN via the light emitting element LD in response to the voltage of the third node N3. During the fourth period T4, the light emitting element LD may generate light with a luminance corresponding to the amount of driving current supplied from the first transistor M1.

In the embodiment of the present disclosure, a threshold voltage compensation process will be described in detail. First, during the second period T2, the third node N3 is set to the voltage Vdata of the data signal, and the first node N1 is set to a voltage (Vdata+|Vth (M1) |) obtained by adding the absolute threshold voltage of the first transistor M1 to the voltage Vdata of the data signal. Then, the threshold voltage of the first transistor M1 may be stored in the first capacitor C1. That is, the threshold voltage of the first transistor M1 may be primarily compensated for during the second period T2.

For example, the threshold voltage of the first transistor M1 may be set differently in response to the voltage difference between the body electrode and the source electrode. Assuming that the first power voltage VDD is set to 8V, during the second period T2, the body electrode of the first transistor M1 may be set to 8V, and the source electrode (that is, the first node N1) may be set to a voltage lower than the voltage of the body electrode. For example, assuming that the first node N1 is set to 4V, the voltage difference (for example, VBS=4V) between the body electrode and the source electrode of the first transistor M1 may be set to 4V. In this case, the first transistor M1 may have a first threshold voltage. In the second period T2, the first threshold voltage may be compensated.

In some embodiments, during the fourth period T4, the first node N1 is set to the first power voltage VDD. In this case, the body electrode and the source electrode of the first transistor M1 may be set to the same voltage (that is, VBS=0), and the first transistor M1 may have a second threshold voltage different from the first threshold voltage.

When the first power voltage VDD is supplied to the first node N1 during the fourth period T4, the voltage of the third node N3 may be set as illustrated in Equation 1. According to one or more embodiments of the present disclosure, the process of changing the voltage of the third node N3 may be performed during the third period T3, but is not limited thereto. For better understanding and ease of description, an example will be described that the voltage of the third node N3 is changed during the fourth period T4. For example, the third period T3 is a period that may be omitted, so the voltage of the third node N3 will be described using the fourth period T4.

$$VN 3 a = Vdata + ( VDD - ( Vdata + \vert Vth ( M 1 ) \vert ) ) \times C 1 / ( C 1 + C 2 ) \qquad [ Equation 1 ]$$

In Equation 1, VN3a may mean the voltage of the third node N3 corresponding to the voltage change amount of the first node N1. Referring to Equation 1, the voltage of the first node N1 may be changed from Vdata+| Vth (M1) | to the first power voltage VDD during the fourth period T4. In this case, the voltage of the third node N3 is also changed by the coupling of the first capacitor C1.

Here, the voltage change amount of the third node N3 may be determined in accordance with the ratio of the first capacitor C1 and the second capacitor C2. For example, the voltage of the third node N3 may be changed by a value obtained by multiplying the voltage change amount of the first node N1 by C1/(C1+C2) from the voltage Vdata of the data signal. In an example in which the voltage change amount of the third node N3 is controlled by the ratio of the first capacitor C1 and the second capacitor C2, the voltage range of the data signal may be sufficiently wide. In some aspects, the first capacitor C1 has a higher capacity than the second capacitor C2, and accordingly, the voltage of the third node N3 may be stably changed.

In some embodiments, after the voltage of the third node N3 is set as illustrated in Equation 1, the voltage of the second node N2 may be changed in response to the amount of current supplied from the first transistor M1 to the second node N2 in response to the voltage of the third node N3. In some aspects, the voltage of the third node N3 may be changed as illustrated in Equation 2 in response to the voltage change amount of the second node N2.

$$VN 3 b = VN 3 a + Δ VN 2 \times C 2 / ( C 1 + C 2 ) \qquad [ Equation 2 ]$$

In Equation 2, ΔVN2 may mean the voltage change amount of the second node N2, and VN3b may mean the voltage of the third node N3 corresponding to the voltage change amount ΔVN2 of the second node N2. Referring to Equation 2, during the fourth period T4, the voltage of the third node N3 may be changed by a value obtained by multiplying the voltage change amount ΔVN2 of the second node N2 by C2/(C1+C2).

Here, the voltage change amount ΔVN2 of the second node N2 may be set differently corresponding to the second threshold voltage. That is, the voltage change amount ΔVN2 of the second node N2 may be set differently corresponding to the second threshold voltage, and the second threshold voltage of the first transistor M1 may be compensated by reflecting the voltage change amount ΔVN2 of the second node N2 to the third node N3.

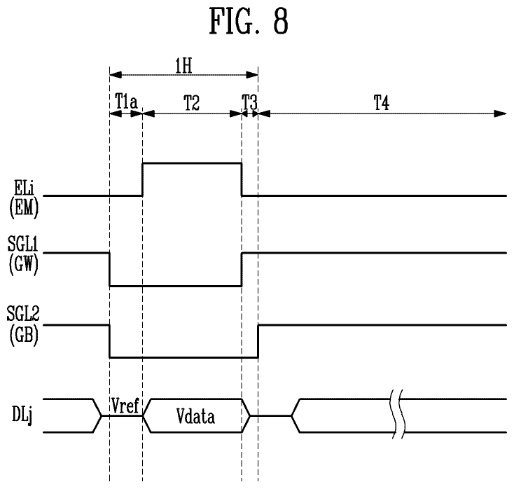

FIG. 8 illustrates a waveform diagram of an embodiment of a driving method of the sub-pixel illustrated in FIG. 4. In describing FIG. 8, descriptions overlapping those of FIG. 6 will be omitted.

Referring to FIG. 8, a horizontal period 1H (or a specific horizontal period) in which the sub-pixel SPij is driven may be divided into a first period T1a, a second period T2, and a third period T3.

The data driver 130 may supply a reference voltage Vref to the data line DLj during the first period Tla and supply the voltage Vdata of the data signal during the second period T2 and the third period T3. The reference voltage Vref may be set to a constant voltage. For example, the reference voltage Vref may be set to a voltage at which the first transistor M1 may be turned on.

During the first period Tla, the first scan signal GW is supplied to the first sub-gate line SGL1, and the second scan signal GB is supplied to the second sub-gate line SGL2. In some aspects, during the first period T1a, the light emitting control signal EM is not supplied to the light emitting control line ELi (or enable light emitting control is supplied), and accordingly, the third transistor M3 is set to the turned-on state. In an example in which the third transistor M3 is set to the turned-on state, the first power voltage VDD may be supplied to the first node N1.

When the first scan signal GW is supplied to the first sub-gate line SGL1, the second transistor M2 is turned on. In an example in which the second transistor M2 is turned on, the reference voltage Vref is supplied from the data line DLj to the third node N3. In this case, the first capacitor C1 may be initialized by the reference voltage Vref and the first power voltage VDD. For example, the first capacitor C1 may charge a voltage corresponding to the reference voltage Vref and the first power voltage VDD during the first period Tla regardless of the voltage charged in the previous period (or the previous frame period).

When the second scan signal GB is supplied to the second sub-gate line SGL2, the fourth transistor M4 is turned on. In an example in which the fourth transistor M4 is turned on, the initialization voltage is supplied to the second node N2. In an example in which the initialization voltage is supplied to the second node N2, the light emitting element LD may be initialized. In an example in which the initialization voltage is supplied to the second node N2, the parasitic capacitor (not illustrated) of the light emitting element LD may be discharged.

The second capacitor C2 may be initialized by the reference voltage Vref supplied to the third node N3 and the initialization voltage supplied to the second node N2. For example, the second capacitor C2 may charge a voltage corresponding to the reference voltage Vref and the initialization voltage during the first period Ta regardless of the voltage charged in the previous period (or the previous frame period).

During the first period T1a, the current supplied from the first transistor M1 may be supplied to the initialization voltage node VINTN via the fourth transistor M4. Accordingly, the light emitting element LD may maintain a non-light emitting state during the first period T1a.

The driving method of FIG. 8 is the same as the driving method of FIG. 6 except that that only the reference voltage Vref is supplied to the data line DLj during the first period T1a.

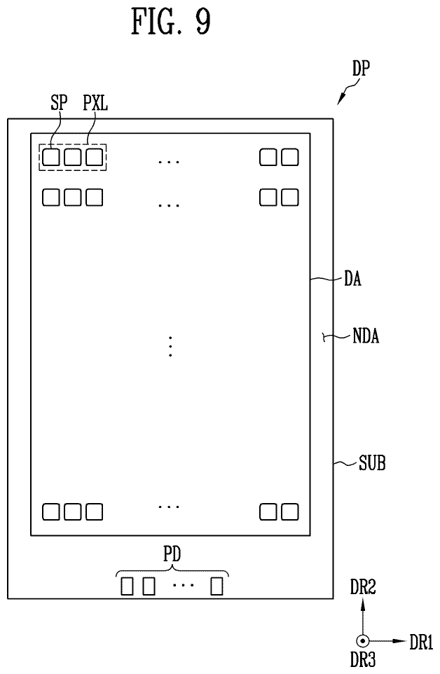

FIG. 9 illustrates a top plan view of an embodiment of a display panel of FIG. 1.

Referring to FIG. 9, an embodiment DP of the display panel 110 of FIG. 1 may include a display area DA and a non-display area NDA. The display panel DP displays an image through the display area DA. The non-display area NDA is disposed around the display area DA.

The display panel DP may include a substrate SUB, sub-pixels SP, and pads PD.

When the display panel DP is used as a display screen for a head mounted display (HMD), a virtual reality (VR) device, a mixed reality (MR) device, or an augmented reality (AR) device, the display panel DP may be positioned very close to the user's eyes. In this case, sub-pixels SP with relatively high integration may be required, and the display panel DP may be implemented with such high integration of sub-pixels SP. In order to increase the integration of the sub-pixels SP, the substrate SUB may be provided as a silicon substrate. The sub-pixels SP and/or the display panel DP may be formed on the substrate SUB, which is a silicon substrate. The display device 100 (see FIG. 1) including the display panel DP formed on the substrate SUB, which is a silicon substrate, may be referred to as an OLED on silicon (OLEDoS) display device.

The sub-pixels SP are disposed in the display area DA on the substrate SUB. The sub-pixels SP may be arranged in a matrix format along a first direction DR1 and a second direction DR2 that intersects the first direction DR1. However, embodiments are not limited thereto. For example, the sub-pixels SP may be arranged in a zigzag form along first direction DR1 and second direction DR2. For example, the sub-pixels SP may be disposed in a PENTILE™ shape. The first direction DR1 may be a row direction, and the second direction DR2 may be a column direction.

Two or more of the plurality of sub-pixels SP may configure one pixel PXL.

A constituent element to control the sub-pixels SP may be disposed in the non-display area NDA on the substrate SUB. For example, wires connected to the sub-pixels SP, such as, for example, the first to m-th gate lines GL1 to GLm and the first to n-th data lines DL1 to DLn of FIG. 1, may be disposed in the non-display area NDA.

At least one of the gate driver 120, the data driver 130, the voltage generator 140, the controller 150, and the temperature sensor 160 in FIG. 1 may be integrated in the non-display area NDA of the display panel DP. In embodiments, the gate driver 120 of FIG. 1 may be mounted on the display panel DP, and may be disposed in the non-display area NDA. In other embodiments, the gate driver 120 may be implemented as an integrated circuit separated from the display panel DP. In embodiments, the temperature sensor 160 may be disposed in the non-display area NDA to detect the temperature of the display panel DP.

The pads PD are disposed in the non-display area NDA on the substrate SUB. The pads PD may be electrically connected to the sub-pixels SP through wires. For example, the pads PD may be connected to the sub-pixels SP through the first to n-th data lines DL1 to DLn.

The pads PD may interface the display panel DP to other constituent elements of the display device 100 (see FIG. 1). In embodiments, voltages and signals supportive of (e.g., required for) operations of constituent elements included in the display panel DP may be provided from the driver integrated circuit DIC of FIG. 1 through the pads PD. For example, the first to n-th data lines DL1 to DLn may be connected to the driver integrated circuit DIC through the pads PD. For example, the first and second power voltages VDD and VSS may be received from the voltage generator 140 through the pads PD. In an example in which the gate driver 120 is mounted on the display panel DP, the gate control signal GCS may be transmitted from the driver integrated circuit DIC to the gate driver 120 through the pads PD.

In embodiments, the circuit board may be electrically connected to the pads PD by using a conductive adhesive member such as, for example, an anisotropic conductive film. In this case, the circuit board may be a flexible printed circuit board (FPCB) or a flexible film formed of a flexible material. The driver integrated circuit DIC may be mounted on the circuit board to be electrically connected to the pads PD.

In embodiments, the display area DA may have various shapes. The display area DA may have a closed-loop shape including sides of a straight line and/or a curved line. For example, the display area DA may have shapes such as, for example, a polygonal shape, a circular shape, a semicircular, and an elliptical shape.

In embodiments, the display panel DP may have a flat display surface. In other embodiments, the display panel DP may have a display surface that is at least partially round. In embodiments, the display panel DP may be bendable, foldable, or rollable. In these cases, the display panel DP and/or the substrate SUB may include materials with flexible properties.

FIG. 10 illustrates an exploded perspective view of a portion of the display panel of FIG. 9. In FIG. 10, for clear and concise description, a portion of the display panel DP corresponding to two pixels PXL1 and PXL2 among the pixels PXL of FIG. 9 is schematically illustrated. Portions of the display panel DP corresponding to the remaining pixels may be similarly configured.

Referring to FIG. 9 and FIG. 10, each of the first and second pixels PXL1 and PXL2 may include first to third sub-pixels SP1, SP2, and SP3. However, embodiments are not limited thereto. For example, each of the first and second pixels PXL1 and PXL2 may include four sub-pixels, or two sub-pixels.

In FIG. 10, the first to third sub-pixels SP1, SP2, and SP3 are illustrated to have quadrangular shapes and have the same sizes when viewed in the third direction DR3 crossing the first and second directions DR1 and DR2. However, embodiments are not limited thereto. The first to third sub-pixels SP1, SP2, and SP3 may be modified to have various shapes.

The display panel DP may include a substrate SUB, a pixel circuit layer PCL, a light emitting element layer LDL, an encapsulation layer TFE, an optical functional layer OFL, an overcoat layer OC, and a cover window CW.

In embodiments, the substrate SUB may include a silicon wafer substrate formed using a semiconductor process. The substrate SUB may include a semiconductor material suitable for forming circuit elements. For example, the semiconductor material may include silicon, germanium, and/or silicon-germanium. The substrate SUB may be provided from a bulk wafer, an epitaxial layer, an epitaxial layer, a silicon on Insulator (SOI) layer, or a semiconductor on insulator (SeOI) layer. In other embodiments, the substrate SUB may include a glass substrate. In still other embodiments, the substrate SUB may include a polyimide (PI) substrate.

The pixel circuit layer PCL is disposed on the substrate SUB. The substrate SUB and/or the pixel circuit layer PCL may include insulating layers and conductive patterns disposed between the insulating layers. The conductive patterns of the pixel circuit layer PCL may function as at least some of circuit elements, wires, and the like

The conductive patterns may include copper, but embodiments are not limited thereto.

The circuit elements may include the sub-pixel circuit SPC (see FIG. 4) for each of first to third sub-pixels SP1, SP2, and SP3. The sub-pixel circuit SPC may include transistors and one or more capacitors. Each transistor may include a semiconductor portion including a source area, a drain area, and a channel area, and a gate electrode overlapping the semiconductor portion. In some aspects, the transistor may further include a body electrode.

In embodiments, when the substrate SUB is provided as a silicon substrate, the semiconductor portion may be included in the substrate SUB, and the gate electrode may be included in the pixel circuit layer PCL as the conductive pattern of the pixel circuit layer PCL. In embodiments, when the substrate SUB is provided as a glass substrate or a PI substrate, the semiconductor portion and the gate electrode may be included in the pixel circuit layer PCL.

The first capacitor C1 may be a metal-oxide-semiconductor (MOS) capacitor, and may be formed on the same layer as the transistors. For example, the first capacitor C1 may include a source area, a drain area, a channel area, a body electrode, and a gate electrode. The first capacitor C1 may be driven as a capacitor by applying the same voltage (for example, the first power voltage VDD) to the source area, the drain area, and the body electrode. The first capacitor C1 may be formed simultaneously with the transistors.

The second capacitor C2 may be a metal-oxide-metal (MOM) capacitor, and may be formed on a different layer from the transistors. For example, the first electrode and the second electrode of the second capacitor C2 may be formed on the same layer. Different voltages are applied to the first electrode and the second electrode of the second capacitor C2 to be driven as a capacitor. The first electrode and the second electrode of the second capacitor C2 may be formed to have various shapes adjacent to each other. The second capacitor C2 may be formed at a different time from the transistors.

The wires of the pixel circuit layer PCL may include signal lines connected to each of the first to third sub-pixels SP1, SP2, and SP3 for example, a gate line, a light emitting control line, and a data line. The wires may further include the wire connected to the first power voltage node VDDN of FIG. 2. In some aspects, the wires may further include the wire connected to the second power voltage node VSSN of FIG. 2.

The light emitting element layer LDL may include anode electrodes AE, a pixel defining film PDL, a light emitting structure EMS, and a cathode electrode CE.

The anode electrodes AE may be disposed on the pixel circuit layer PCL. The anode electrodes AE may contact circuit elements of the pixel circuit layer PCL. The anode electrodes AE may include an opaque conductive material capable of reflecting light, but embodiments are not limited thereto.

The pixel defining film PDL is disposed on the anode electrodes AE. The pixel defining film PDL may include an opening OP exposing a portion of each of the anode electrodes AE. The opening OP of the pixel defining film PDL may be understood as light emitting areas corresponding to the first to third sub-pixels SP1 to SP3, respectively.

In embodiments, the pixel defining film PDL may include an inorganic material. In this case, the pixel defining film PDL may include a plurality of stacked inorganic layers. For example, the pixel defining film PDL may include a silicon oxide (SiOx) and a silicon nitride (SiNx). In other embodiments, the pixel defining film PDL may include an organic material. However, the material of the pixel defining film PDL is not limited thereto.

The light emitting structure EMS may be disposed on the anode electrodes AE exposed by the opening OP of the pixel defining film PDL. The light emitting structure EMS may include a light emitting layer configured to generate light, an electron transport layer configured to transport electrons, and a hole transport layer configured to transport holes.

In embodiments, the light emitting structure EMS may fill the opening OP of the pixel defining film PDL, and may be disposed entirely on an upper portion of the pixel defining film PDL. In other words, the light emitting structure EMS may extend across the first to third sub-pixels SP1 to SP3. In this case, at least some of the functional layers in the light emitting structure EMS may be disconnected or bent at the boundaries between the first to third sub-pixels SP1 to SP3. However, embodiments are not limited thereto. For example, portions of the light emitting structure EMS corresponding to the first to third sub-pixels SP1 to SP3 are separated from each other, and each of the portions may be disposed in the opening OP of the pixel defining film PDL.

The cathode electrode CE may be disposed on the light emitting structure EMS. The cathode electrode CE may extend across the first to third sub-pixels SP1 to SP3. As such, the cathode electrode CE may be provided as a common electrode for the first to third sub-pixels SP1 to SP3.

The cathode electrode CE may be a thin metal layer with a thickness sufficient to transmit light emitted from the light emitting structure EMS. The cathode electrode CE may be formed of a metallic material or a transparent conductive material to have a relatively thin thickness. In embodiments, the cathode electrode CE may include at least one of various transparent conductive materials including an indium tin oxide, an indium zinc oxide, an indium tin zinc oxide, an aluminum zinc oxide, a gallium zinc oxide, a zinc tin oxide, and a gallium tin oxide. In other embodiments, the cathode electrode CE may include at least one of silver (Ag), magnesium (Mg), and a mixture thereof. However, the material of the cathode electrode CE is not limited thereto.

One of the anode electrodes AE, the portion of the light emitting structure EMS overlapping the anode electrodes AE, and the portion of the cathode electrode CE overlapping the anode electrodes AE may be understood to constitute one light emitting element LD (see FIG. 2). In other words, each of the light emitting elements of the first to third sub-pixels SP1 to SP3 may include one anode electrode, a portion of the light emitting structure EMS overlapping the anode electrode, and a portion of the cathode electrode CE overlapping the anode electrode. In each of the first to third sub-pixels SP1 to SP3, holes injected from the anode electrode AE and electrons injected from the cathode electrode CE are transported into the light emitting layer of the light emitting structure EMS to form excitons, and when the excitons transition from the excited state to the ground state, light may be generated. The luminance of light may be determined depending on the amount of current flowing through the light emitting layer. Depending on the configuration of the light emitting layer, the wavelength range of the generated light may be determined.

The encapsulation layer TFE is disposed on the cathode electrode CE. The encapsulation layer TFE may cover the light emitting element layer LDL and/or the pixel circuit layer PCL. The encapsulation layer TFE may be configured to prevent oxygen and/or moisture from penetrating into the light emitting element layer LDL. In embodiments, the encapsulation layer TFE may include a structure in which one or more inorganic films and one or more organic films are alternately stacked. For example, the inorganic film may include a silicon nitride, a silicon oxide, or a silicon oxynitride (SiOxNy). For example, the organic film may include an organic insulating material such as, for example, an acrylic resin, an epoxy resin, a phenol resin, a polyamide resin, a polyimide resin, an unsaturated polyesters resin, a polyphenylenethers resin, a polyphenylenesulfides resin, or a benzocyclobutene. However, the materials of the organic film and the inorganic film of the encapsulation layer TFE are not limited thereto.

The encapsulation layer TFE may further include a thin film containing an aluminum oxide (AIOx) in order to improve the encapsulation efficiency of the encapsulation layer TFE. The thin film containing an aluminum oxide may be disposed on the upper surface of the encapsulation layer TFE facing the optical functional layer OFL and/or the lower surface of the encapsulation layer TFE facing the light emitting element layer LDL.

The thin film containing the aluminum oxide may be formed through atomic layer deposition (ALD). However, embodiments are not limited thereto. The encapsulation layer TFE may further include a thin film formed of at least one of various materials suitable for improving the encapsulation efficiency.

The optical functional layer OFL is disposed on the encapsulation layer TFE. The optical functional layer OFL may include a color filter layer CFL and a lens array LA.

The color filter layer CFL is disposed between the encapsulation layer TFE and the lens array LA. The color filter layer CFL is configured to selectively output light in a wavelength range or color corresponding to each sub-pixel by filtering light emitted from the light emitting structure EMS. The color filter layer CFL includes color filters CF respectively corresponding to the first to third sub-pixels SP1 to SP3), and each of the color filters CF may pass light in a wavelength range corresponding to the sub-pixel. For example, a color filter corresponding to the first sub-pixel SP1 may pass red light, a color filter corresponding to the second sub-pixel SP2 may pass green light, and a color filter corresponding to the third sub-pixel SP3 may pass blue light. At least some of the color filters CF may be omitted according to light emitted from the light emitting structure EMS of each sub-pixel.

The lens array LA is disposed on the color filter layer CFL. The lens array LA may include lenses LS respectively corresponding to the first to third sub-pixels SP1 to SP3. Each of the lenses LS may improve light output efficiency by outputting light emitted from the light emitting structure EMS in an intended path. The lens array LA may have a relatively high refractive index. For example, the lens array LA may have a higher refractive index than the overcoat layer OC. In embodiments, the lenses LS may include an organic material. In embodiments, the lenses LS may include an acrylic material. However, the material of the lenses LS is not limited thereto.

In embodiments, compared to the opening OP of the pixel defining film PDL, at least some of the color filters CF of the color filter layer CF and at least some of the lenses LS of the lens array LA may be shifted in a direction parallel to a plane defined by the first and second directions DR1 and DR2. Specifically, in the center area of the display area DA, the center of the color filter and the center of the lens may be aligned or overlapped with the center of the opening OP of the corresponding pixel defining film PDL when viewed in the third direction DR3. For example, in the central area of the display area DA, the opening OP of the pixel defining film PDL may completely overlap the corresponding color filter of the color filter layer CF and the corresponding lens of the lens array LA. In an area of the display area DA adjacent to the non-display area NDA, the center of the color filter and the center of the lens may be shifted in a planar direction from the center of the opening OP of the corresponding pixel defining film PDL when viewed in the third direction DR3. For example, in an area of the display area DA adjacent to the non-display area NDA, the opening OP of the pixel defining film PDL may partially overlap the corresponding color filter of the color filter layer CFL and the corresponding lens of the lens array LA. Accordingly, in the center of the display area DA, light emitted from the light emitting structure EMS may be efficiently outputted in the normal direction of the display surface. Light emitted from the light emitting structure EMS at the outside of the display area DA may be efficiently outputted in a direction inclined by a predetermined angle with respect to the normal direction of the display surface.

The overcoat layer OC may be disposed on the lens array LA. The overcoat layer OC may cover the optical functional layer OFL, the encapsulation layer TFE, the light emitting structure EMS, and/or the pixel circuit layer PCL. The overcoat layer OC may include various materials suitable for protecting lower layers of the display panel DP (e.g., layers below the overcoat layer) from foreign substances such as, for example, dust and moisture. For example, the overcoat layer OC may include at least one of an inorganic insulating film and an organic insulating film. For example, the overcoat layer OC may include an epoxy resin, but embodiments are not limited thereto. The overcoat layer OC may have a lower refractive index than the lens array LA.

The cover window CW may be disposed on the overcoat layer OC. The cover window CW is configured to protect lower layers of the display panel DP (e.g., layers below the cover window CW). The cover window CW may have a higher refractive index than the overcoat layer OC. The cover window CW may include glass, but embodiments are not limited thereto. For example, the cover window CW may be an encapsulation glass configured to protect constituent elements disposed thereunder. In other embodiments, the cover window CW may be omitted.

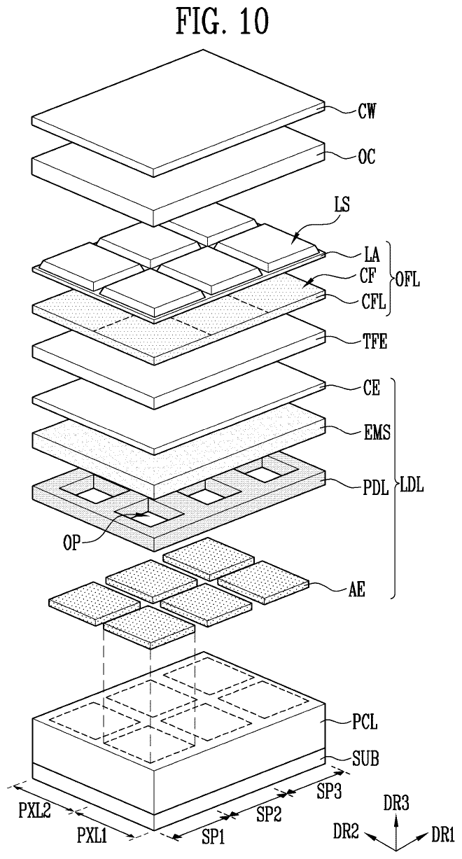

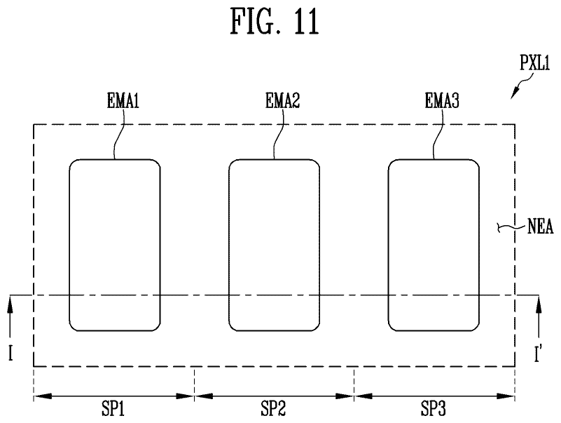

FIG. 11 illustrates a top plan view of an example of one of pixels of FIG. 10. For a clear and concise description in FIG. 11, the first pixel PXL1 among the first and second pixels PXL1 and PXL2 of FIG. 10 is schematically illustrated. The remaining pixels may be configured similarly to the first pixel PXL1.

Referring to FIG. 10 and FIG. 11, a first pixel PXL1 may include the first to third sub-pixels SP1 to SP3 disposed in the first direction DR1.

The first sub-pixel SP1 may include a first light emitting area EMA1 and a non-light emitting area NEA around the first light emitting area EMA1. The second sub-pixel SP2 may include a second light emitting area EMA2 and a non-light emitting area NEA around the second light emitting area EMA2. The third sub-pixel SP3 may include a third light emitting area EMA3 and a non-light emitting area NEA around the third light emitting area EMA3.

The first light emitting area EMA1 may be an area in which light is emitted from a portion of the light emitting structure EMS (see FIG. 10) corresponding to the first sub-pixel SP1. The second light emitting area EMA2 may be an area in which light is emitted from a portion of the light emitting structure EMS corresponding to the second sub-pixel SP2. The third light emitting area EMA3 may be an area in which light is emitted from a portion of the light emitting structure EMS corresponding to the third sub-pixel SP3. As described with reference to FIG. 10, each light emitting area may be understood as the opening OP of the pixel defining film PDL corresponding to each of the first to third sub-pixels SP1 to SP3.

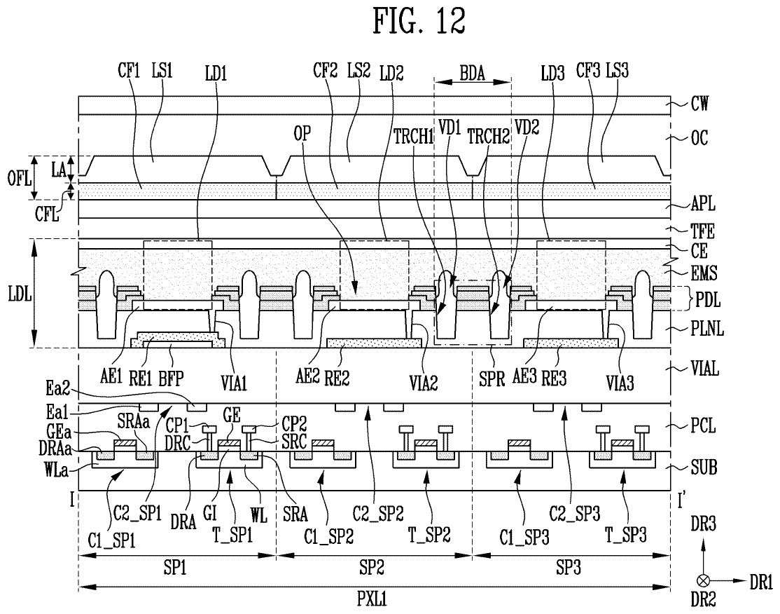

FIG. 12 illustrates a cross-sectional view taken along line I-I′ of FIG. 11.

Referring to FIG. 12, the substrate SUB and the pixel circuit layer PCL disposed on the substrate SUB are provided.

The substrate SUB may include a silicon wafer substrate formed using a semiconductor process. For example, the substrate SUB may include silicon, germanium, and/or silicon-germanium.

The pixel circuit layer PCL is disposed on the substrate SUB. The substrate SUB and the pixel circuit layer PCL may include circuit elements for each of the first to third sub-pixels SP1 to SP3. For example, the substrate SUB and the pixel circuit layer PCL may include a transistor T_SP1 and a first capacitor C1_SP1 of the first sub-pixel SP1, a transistor T_SP2 and a first capacitor C1_SP2 of the second sub-pixel SP2, and a transistor T_SP3 and a first capacitor C1_SP3 of the third sub-pixel SP3.

The transistor T_SP1 of the first sub-pixel SP1 may be one of the transistors included in the sub-pixel circuit SPC (see FIG. 2) of the first sub-pixel SP1, the transistor T_SP2 of the second sub-pixel SP2 may be one of the transistors included in the sub-pixel circuit SPC of the second sub-pixel SP2, and the transistor T_SP3 of the third sub-pixel SP3 may be one of the transistors included in the sub-pixel circuit SPC of the third sub-pixel SP3. In FIG. 12, for clear and concise description, one of the transistors of each sub-pixel is illustrated and the remaining transistors are omitted.

The first capacitor C1_SP1 of the first sub-pixel SP1 means the first capacitor C1 included in the first sub-pixel SP1, the first capacitor C1_SP2 of the second sub-pixel SP2 means the first capacitor C1 included in the second sub-pixel SP2, and the first capacitor C1_SP3 of the third sub-pixel SP3 means the first capacitor C1 included in the third sub-pixel SP3.

The transistor T_SP1 of the first sub-pixel SP1 may include a source area SRA, a drain area DRA, and a gate electrode GE. The source area SRA and the drain area DRA may be disposed within the substrate SUB. A well WL formed through an ion injection process is disposed in the substrate SUB, and the source area SRA and the drain area DRA may be disposed spaced apart from each other within the well WL. The area between the source area SRA and the drain area DRA within the well WL may be defined as a channel area. In some aspects, the first sub-pixel SP1 further includes a body electrode that is not illustrated, and the body electrode may be disposed at the lower end portion of the well WL to be connected to the well WL (for example, between the well WL and the substrate SUB). The body electrode may receive the first power voltage VDD via a contact portion (not illustrated).

The gate electrode GE overlaps the channel area between the source area SRA and the drain area DRA, and may be disposed on the pixel circuit layer PCL. The gate electrode GE may be separated from the well WL or the channel area by an insulating material such as, for example, a gate insulating layer GI. The gate electrode GE may include a conductive material.

A plurality of layers included in the pixel circuit layer PCL include insulating layers and conductive patterns disposed between the insulating layers, and the conductive patterns may include first and second conductive patterns CP1 and CP2. The first conductive pattern CP1 may be electrically connected to the drain area DRA through a drain connection portion DRC penetrating one or more insulating layers. The second conductive pattern CP2 may be electrically connected to the source area SRA through a source connection portion SRC penetrating one or more insulating layers.

As the gate electrode GE and the first and second conductive patterns CP1 and CP2 are connected to other circuit elements and/or wires, the transistor T_SP1 of the first sub-pixel SP1 may be provided as one of the transistors of the first sub-pixel SP1.

The first capacitor C1_SP1 of the first sub-pixel SP1 may be a metal-oxide-semiconductor (MOS) capacitor, and may be formed on the same layer as the transistors of the first sub-pixel SP1. The first capacitor C1_SP1 may include a source area SRAa, a drain area DRAa, and a gate electrode GEa. In some aspects, the first capacitor C1_SP1 may further include a body electrode disposed such that the body electrode is connected to the well WL. In some aspects, the first capacitor C1_SP1 of the first sub-pixel SP1 may further include a first conductive pattern (not illustrated) electrically connected to the drain area DRAa and a second conductive pattern (not illustrated) electrically connected to the source area SRAa. The source area SRAa, the drain area DRAa, and the body electrode of the first capacitor C1_SP1 of the first sub-pixel SP1 may receive the first power voltage VDD.

The transistor T_SP2 and the first capacitor C1_SP2 of the second sub-pixel SP2, and the transistor T_SP3 and the first capacitor C1_SP3 of the third sub-pixel SP3 may be respectively configured similarly to the transistor T_SP1 and the first capacitor C1_SP1 of the first sub-pixel SP1.

A plurality of layers included in the pixel circuit layer PCL include insulating layers and conductive patterns disposed between the insulating layers, and the conductive patterns may form the first electrode Ea1 and the second electrode Ea2 of the second capacitors C2_SP1, C2_CP2, and C2_SP3. For example, the second capacitor C2_SP1 of the first sub-pixel SP1 may be formed to overlap the first sub-pixel SP1 in the third direction DR3, the second capacitor C2_SP2 of the second sub-pixel SP2 may be formed to overlap the second sub-pixel SP2 in the third direction DR3, and the second capacitor C2_SP3 of the third sub-pixel SP3 may be formed to overlap the third sub-pixel SP3 in the third direction DR3.

The second capacitor C2_SP1 of the first sub-pixel SP1 may be a metal-oxide-metal (MOM) capacitor, and may be formed on a different layer from the transistor T_SP1 of the first sub-pixel SP1. The first electrode Eal and the second electrode Ea2 of the second capacitor C2_SP1 of the first sub-pixel SP1 may be formed on the same layer. The second capacitor C2_SP1 of the first sub-pixel SP1 may be in contact with a circuit element disposed in the pixel circuit layer PCL.

As described herein, the substrate SUB and the pixel circuit layer PCL may include the circuit elements for each of the first to third sub-pixels SP1 to SP3.

A via layer VIAL is disposed on the pixel circuit layer PCL. The via layer VIAL covers the pixel circuit layer PCL, and may have an overall flat surface. The via layer VIAL is configured to flatten steps on the pixel circuit layer PCL. The via layer VIAL may include at least one of a silicon oxide (SiOx), a silicon nitride (SiNx), and a silicon carbon nitride (SiCN), but embodiments are not limited thereto.

The light emitting element layer LDL is disposed on the via layer VIAL. The light emitting element layer LDL may include first to third reflective electrodes RE1 to RE3, a planarization layer PLNL, first to third anode electrodes AE1 to AE3, a pixel defining film PDL, a light emitting structure EMS, and a cathode electrode CE.

The first to third reflective electrodes RE1 to RE3 are disposed in the first to third sub-pixels SP1 to SP3 on the via layer VIAL, respectively. Each of the first to third reflective electrodes RE1 to RE3 may contact a circuit element disposed on the pixel circuit layer PCL through a via penetrating the via layer VIAL.

The first to third reflective electrodes RE1 to RE3 may function as full mirrors that reflect light emitted from the light emitting structure EMS toward the display surface (or the cover window CW). The first to third reflective electrodes RE1 to RE3 may include metallic materials suitable for reflecting light. The first to third reflective electrodes RE1 to RE3 may include at least one of aluminum (Al), silver (Ag), magnesium (Mg), platinum (Pt), palladium (Pd), gold (Au), nickel (Ni), neodymium (Nd), iridium (Ir), chromium (Cr), titanium (Ti), and an alloy of two or more materials selected therefrom, but embodiments are not limited thereto.

In embodiments, a connection electrode may be disposed below each of the first to third reflective electrodes RE1 to RE3. The connection electrode may improve the electrical connection characteristics between the corresponding reflective electrode and the circuit element of the pixel circuit layer PCL. The connection electrode may have a multi-layered structure. The multi-layered structure may include titanium (Ti), a titanium nitride (TiN), a tantalum nitride (TaN), and the like, but embodiments are not limited thereto. In embodiments, a corresponding reflective electrode may be disposed between the multiple layers of the connecting electrode.

A buffer pattern BFP may be disposed below at least one of the first to third reflective electrodes RE1 to RE3. The buffer pattern BFP may include an inorganic material such as, for example, a silicon carbon nitride, but embodiments are not limited thereto. By disposing the buffer pattern BFP, the height of the corresponding reflective electrode in the third direction DR3 may be adjusted. For example, the buffer pattern BFP may be disposed between the first reflective electrode RE1 and the via layer VIAL to adjust the height of the first reflective electrode RE1.

The first to third reflective electrodes RE1 to RE3 may function as full mirrors, and the cathode electrode CE may function as a half mirror. Light emitted from the light emitting layer of the light emitting structure EMS may be amplified at least partially by reciprocating between the reflective electrode and the cathode electrode CE, and the amplified light may be outputted through the cathode electrode CE. As such, the distance between each reflective electrode and the cathode electrode CE may be understood as the resonance distance for the light emitted from the light emitting layer of the corresponding light emitting structure EMS.

The first sub-pixel SP1 may have a shorter resonance distance than other sub-pixels due to the buffer pattern BFP. The resonance distance adjusted in this way may allow light in a specific wavelength range (for example, red color) to be effectively and efficiently amplified. Accordingly, the first sub-pixel SP1 may effectively and efficiently output light in the corresponding wavelength range.

In FIG. 12, the buffer pattern BFP is illustrated in which the buffer pattern BFP is provided in the first sub-pixel SP1 and not in the second and third sub-pixels SP2 and SP3, but the embodiments are not limited thereto. Additionally, or alternatively, the buffer pattern BFP may be provided in at least one of the second and third sub-pixels SP2 and SP3, such that the resonance distance of at least one of the second and third sub-pixels SP2 and SP3 is adjusted. For example, the first to third sub-pixels SP1 to SP3 may correspond to red, green, and blue, respectively, the distance between the first reflective electrode RE1 and the cathode electrode CE may be shorter than the distance between the second reflective electrode RE2 and the cathode electrode CE, and the distance between the second reflective electrode RE2 and the cathode electrode CE may be shorter than the distance between the third reflective electrode RE3 and the cathode electrode CE.

To planarize the steps between the first to third reflective electrodes RE1 to RE3, the planarization layer PLNL may be disposed on the via layer VIAL and the first to third reflective electrodes RE1 to RE3. The planarization layer PLNL may entirely cover the first to third reflective electrodes RE1 to RE3 and the via layer VIAL, and may have a flat surface. In embodiments, the planarization layer PLNL may be omitted.

The first to third anode electrodes AE1 to AE3 respectively overlapping the first to third reflective electrodes RE1 to RE3 are disposed on the planarization layer PLNL. The first to third anode electrodes AE1 to AE3 may have shapes similar to the first to third light emitting areas EMA1 to EMA3 of FIG. 11 when viewed in the third direction DR3. The first to third anode electrodes AE1 to AE3 are respectively connected to the first to third reflective electrodes RE1 to RE3. The first anode electrode AE1 may be connected to the first reflective electrode RE1 through the first via VIA1 penetrating the planarization layer PLNL. The second anode electrode AE2 may be connected to the second reflective electrode RE2 through the second via VIA2 penetrating the planarization layer PLNL. The third anode electrode AE3 may be connected to the third reflective electrode RE3 through the third via VIA3 penetrating the planarization layer PLNL.

In embodiments, the first to third anode electrodes AE1 to AE3 may include at least one of a transparent conductive materials such as, for example, an indium tin oxide (ITO), an indium zinc oxide (IZO), a zinc oxide (ZnOx), an indium gallium zinc oxide (IGZO), and an indium tin zinc oxide (ITZO). However, the materials of the first to third anode electrodes AE1 to AE3 are not limited thereto. For example, the first to third anode electrodes AE1 to AE3 may each include a titanium nitride.

In embodiments, insulating layers for adjusting a height of one or more of the first to third anode electrodes AE1 to AE3 may be further provided. The insulating layers may be disposed between one or more of the first to third anode electrodes AE1 to AE3 and the corresponding reflective electrodes. In this case, the planarization layer PLNL and/or the buffer pattern BFP may be omitted. For example, the first to third sub-pixels SP1 to SP3 may respectively correspond to red, green, and blue, the distance between the first anode electrode AE1 and the cathode electrode CE may be shorter than the distance between the second anode electrode AE2 and the cathode electrode CE, and the distance between the second anode electrode AE2 and the cathode electrode CE may be shorter than the distance between the third anode electrode AE3 and the cathode electrode CE. The pixel defining film PDL is disposed on some of the first to third anode electrodes AE1 to AE3 and the planarization layer PLNL. The pixel defining film PDL may include an opening OP exposing a portion of each of the first to third anode electrodes AE1 to AE3. The opening OP of the pixel defining film PDL may define the light emitting area for each of the first to third sub-pixels SP1 to SP3. As such, the pixel defining film PDL may be disposed in the non-light emitting area NEA of FIG. 11 and define the first to third light emitting areas EMA1 to EMA3 of FIG. 11.

In embodiments, the pixel defining film PDL may include a plurality of inorganic insulating layers. Each of the plurality of inorganic insulating layers may include at least one of a silicon oxide (SiOx) and a silicon nitride (SINx). For example, the pixel defining film PDL may include first to third inorganic insulating layers sequentially stacked, and each of the first to third inorganic insulating layers may include a silicon nitride, a silicon oxide, and a silicon oxynitride. However, embodiments are not limited thereto. The first to third inorganic insulating layers may have a step-shaped cross-section in an area adjacent to the opening OP.

A separator SPR may be provided in the boundary area BDA between the sub-pixels SP adjacent to each other. In other words, the separator SPR may be provided in each of the boundary areas between the sub-pixels SP in FIG. 9.

The separator SPR may cause a discontinuity to be formed within the light emitting structure EMS in the boundary area BDA. For example, the light emitting structure EMS may be disconnected bent in the boundary area BDA by the separator SPR.

The separator SPR may be provided in or on the pixel defining film PDL. The pixel defining film PDL may include one or more trenches TRCH1 and TRCH2 as the separator SPR in the boundary area BDA. In embodiments, as illustrated in FIG. 12, one or more trenches TRCH1 and TRCH2 may penetrate the pixel defining film PDL and partially penetrate the planarization layer PLNL. In other embodiments, one or more trenches TRCH1 and TRCH2 may penetrate the pixel defining film PDL and the planarization layer PLNL, and may partially penetrate the via layer VIAL. In other embodiments, one or more trenches TRCH1 and TRCH2 at least partially penetrate the planarization layer PLNL and/or the via layer VIAL, and a portion of the pixel defining film PDL may be disposed in one or more trenches TRCH1 and TRCH2.

FIG. 12 illustrates that two trenches TRCH1 and TRCH2 are provided in the boundary area BDA. However, embodiments are not limited thereto. For example, the pixel defining film PDL may include one trench in the boundary area BDA. Alternatively, the pixel defining film PDL may include three or more trenches in the boundary area BDA.

Due to the first and second trenches TRCH1 and TRCH2, discontinuous portions such as, for example, the first void VD1 and the second void VD2 may be formed in the light emitting structure EMS in the boundary area BDA. Some of the plurality of layers stacked in the light emitting structure EMS may be disconnected or bent by the first and second voids VD1 and VD2. For example, at least one charge generation layer included in the light emitting structure EMS may be disconnected in the first and second voids VD1, and VD2. As described herein, due to the first and second trenches TRCH1 and TRCH2, the portions of the light emitting structure EMS included in the first to third sub-pixels SP1 to SP3 may be at least partially separated.

In FIG. 12, it is illustrated that the first and second voids VD1 and VD2 are formed in the light emitting structure EMS in the boundary area BDA, but this is an example, and the embodiments are not limited thereto. For example, a valley of a concave shape may be formed in the light emitting structure EMS in the boundary area BDA. Depending on the shapes of the first and second trenches TRCH1 and TRCH2, the discontinuities formed in the light emitting structure EMS may vary.

In embodiments, the light emitting structure EMS may be formed through processes such as, for example, vacuum deposition or inkjet printing. In this case, the same materials as the light emitting structure EMS may be disposed on the bottom surfaces of the first and second trenches TRCH1 and TRCH2 adjacent to the via layer VIAL.

The separator SPR may be variously deformed to allow the light emitting structure EMS to be able to have a discontinuity in the boundary area BDA. For example, based on a shape of the separator SPR, the light emitting structure EMS may be discontinuous in the boundary area BDA. In embodiments, inorganic insulating patterns additionally stacked on the pixel defining film PDL in the boundary area BDA may be provided without the first and second trenches TRCH1 and TRCH2. A width of the uppermost inorganic insulating pattern among the additionally stacked inorganic insulating patterns may be greater than a width of the inorganic insulating pattern disposed directly below the uppermost inorganic insulating pattern. For example, in the boundary area BDA, the first to third inorganic insulating patterns are sequentially stacked from the pixel defining film PDL, and the uppermost third inorganic insulating pattern may have a larger width than the second inorganic insulating pattern. For example, the pixel defining film PDL may have a cross-section of a “T” or “I” shape in the boundary area BDA. Depending on the shape of the pixel defining film PDL, a plurality of layers included in the light emitting structure EMS may be at least partially disconnected or bent in the boundary area BDA.

The light emitting structure EMS may be disposed on the anode electrodes AE exposed by the opening OP of the pixel defining film PDL. The light emitting structure EMS may fill the opening OP of the pixel defining film PDL, and may be disposed entirely across the first to third sub-pixels SP1 to SP3. As described herein, the light emitting structure EMS may be at least partially disconnected or bent in the boundary area BDA by the separator SPR. Accordingly, when the display panel DP operates, current leakage from each of the first to third sub-pixels SP1 to SP3 to the neighboring sub-pixel through the layers included in the light emitting structure EMS may decrease or be prevented. Accordingly, the first to third light emitting elements LD1 to LD3 may operate with relatively high reliability.

The cathode electrode CE may be disposed on the light emitting structure EMS. The cathode electrode CE may be provided commonly for the first to third sub-pixels SP1 to SP3. The cathode electrode CE may function as a half mirror that partially transmits and partially reflects light emitted from the light emitting structure EMS.

The first anode electrode AE1, the portion of the light emitting structure EMS overlapping the first anode electrode AE1, and the portion of the cathode electrode CE overlapping the first anode electrode AE1 may configure the first light emitting element LD1. The second anode electrode AE2, the portion of the light emitting structure EMS overlapping the second anode electrode AE2, and the portion of the cathode electrode CE overlapping the second anode electrode AE2 may configure the second light emitting element LD2. The third anode electrode AE3, the portion of the light emitting structure EMS overlapping the third anode electrode AE3, and the portion of the cathode electrode CE overlapping the third anode electrode AE3 may configure the third light emitting element LD3.

The encapsulation layer TFE is disposed on the cathode electrode CE. The encapsulation layer TFE may prevent oxygen and/or moisture from penetrating into the light emitting element layer LDL.

The optical functional layer OFL is disposed on the encapsulation layer TFE. In embodiments, the optical functional layer OFL may be attached to the encapsulation layer TFE through an adhesive layer APL. For example, the optical functional layer OFL may be separately manufactured to be attached to the encapsulation layer TFE through the adhesive layer APL. The adhesive layer APL may further perform a function of protecting the lower layers including the encapsulation layer TFE.

The optical functional layer OFL may include a color filter layer CFL and a lens array LA. The color filter layer CFL may include first to third color filters CF1 to CF3 respectively corresponding to the first to third sub-pixels SP1 to SP3. The first to third color filters CF1 to CF3 may pass light in different wavelength ranges. For example, the first to third color filters CF1 to CF3 may pass red, green, and blue colored light, respectively.

In embodiments, the first to third color filters CF1 to CF3 may partially overlap in the boundary area BDA. In other embodiments, the first to third color filters CF1 to CF3 may be spaced apart from each other, and a black matrix may be provided between the first to third color filters CF1 to CF3.

The lens array LA is disposed on the color filter layer CFL. The lens array LA may include first to third lenses LS1 to LS3 respectively corresponding to the first to third sub-pixels SP1 to SP3.

The first to third lenses LS1 to LS3 may improve light output efficiency by outputting the light emitted from the first to third light emitting elements LD1 to LD3, respectively, along an intended path.

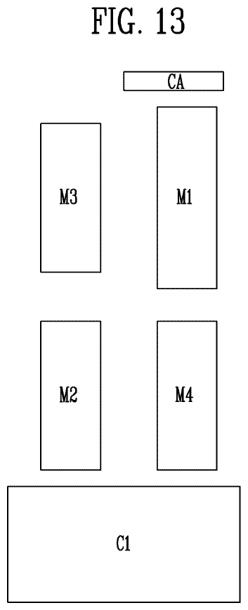

FIG. 13 schematically illustrates circuit elements disposed in a sub-pixel area. The sub-pixel area refers to an area in which circuit elements of the sub-pixel SP are disposed, and the area may become narrower as the resolution increases. FIG. 13 briefly illustrates the mounting area of the transistors M1 to M4 and the first capacitor C1.

Referring to FIG. 13, the transistors M1 to M4 and the first capacitor C1 may be formed in different areas in the sub-pixel area. The contact area CA is an area connected to the body electrodes of the transistors M1 to M4, and may be an area in which contact portions for supplying the first power voltage VDD to the body electrodes are disposed.

The mounting area of the first capacitor C1 may be set to be larger than respective mounting areas of the transistors M1 to M4. In this case, the capacity of the first capacitor C1 may be set sufficiently large, and thus driving stability may be secured. In some aspects, the first capacitor C1 (or the source area SRAa, the drain area DRAa, and the body electrode of the first capacitor C1_SP1) may receive the first power voltage VDD when the third transistor M3 is turned on as illustrated in FIG. 4. Accordingly, a separate contact area is not added, and accordingly, the mounting area of the first capacitor C1 may be set sufficiently large.

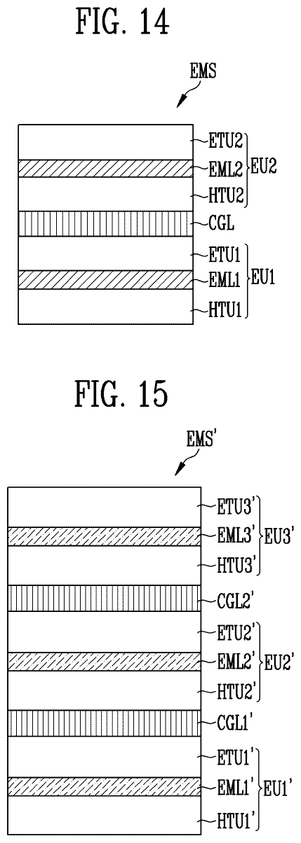

FIG. 14 illustrates a cross-sectional view of an embodiment of a light emitting structure included in one of first to third light emitting elements of FIG. 12.

Referring to FIG. 14, the light emitting structure EMS may have a tandem structure in which first and second light emitting portions EU1 and EU2 are stacked. The light emitting structure EMS may be configured to be substantially the same in each of the first to third light emitting elements LD1 to LD3 of FIG. 12.

Each of the first and second light emitting portions EU1 and EU2 may include at least one light emitting layer that generates light according to a current applied thereto. The first light emitting portion EU1 may include a first light emitting layer EML1, a first electron transport portion ETU1, and a first hole transport portion HTU1. The first light emitting layer EML1 may be disposed between the first electron transport portion ETU1 and the first hole transport portion HTU1. The second light emitting portion EU2 may include a second light emitting layer EML2, a second electron transport portion ETU2, and a second hole transport portion HTU2. The second light emitting layer EML2 may be disposed between the second electron transport portion ETU2 and the second hole transport portion HTU2.

Each of the first and second hole transport portions HTU1 and HTU2 may include at least one of a hole injection layer and a hole transport layer, and may further include a hole buffer layer, an electron blocking layer, or the like as needed. The first and second hole transport portions HTU1 and HTU2 may have the same configuration or different configurations.

Each of the first and second electron transport portions ETU1 and ETU2 may include at least one of an electron injection layer and an electron transport layer, and may further include an electron buffer layer and a hole blocking layer as needed. The first and second electron transport portions ETU1 and ETU2 may have the same configuration or different configurations.

A connection layer, which may be provided in the form of a charge generation layer CGL, may be disposed between the first light emitting portion EU1 and the second light emitting portion EU2 and connect the first light emitting portion EU1 and the second light emitting portion EU2 to each other. In embodiments, the charge generation layer CGL may have a stacked structure of a p dopant layer and an n dopant layer. For example, the p dopant layer may include a p-type dopant such as, for example, HAT-CN, TCNQ, and NDP-9, and the n dopant layer may include an alkali metal, an alkaline earth metal, a lanthanide-based metal, or a combination thereof. However, embodiments are not limited thereto.

In embodiments, the first light emitting layer EML1 and the second light emitting layer EML2 may respectively generate light of different colors. The light emitted from each of the first light emitting layer EML1 and the second light emitting layer EML2 may be mixed to be recognized as white light. For example, the first light emitting layer EML1 may generate blue-colored light, and the second light emitting layer EML2 may generate yellow-colored light. In embodiments, the second light emitting layer EML2 may include a structure in which a first sub-light emitting layer configured to generate red-colored light and a second sub-light emitting layer configured to generate green-colored light are stacked. The red-colored light and the green-colored light may be mixed to provide yellow-colored light. In this case, an intermediate layer configured to perform a function of transporting holes and/or preventing transport of electrons may be further disposed between the first and second sub-light emitting layers.

In other embodiments, the first light emitting layer EML1 and the second light emitting layer EML2 may generate light of the same color.

The light emitting structure EMS may be formed through a vacuum deposition method, an inkjet printing method, or the like, but embodiments are not limited thereto.

FIG. 15 illustrates a cross-sectional view of another embodiment of a light emitting structure included in one of first to third light emitting elements of FIG. 12.

Referring to FIG. 15, a light emitting structure EMS' may have a tandem structure in which first to third light emitting portions EU1′ to EU3′ are stacked. The light emitting structure EMS' may be configured to be substantially the same in each of the first to third light emitting elements LD1 to LD3 of FIG. 12.

Each of the first to third light emitting portions EU1′ to EU3′ may include a light emitting layer that generates light according to a current applied thereto. The first light emitting portion EU1′ may include a first light emitting layer EML1′, a first electron transport portion ETU1′, and a first hole transport portion HTU1′. The first light emitting layer EML1′ may be disposed between the first electron transport portion ETU1′ and the first hole transport portion HTU1′. The second light emitting portion EU2′ may include a second light emitting layer EML2′, a second electron transport portion ETU2′, and a second hole transport portion HTU2′. The second light emitting layer EML2′ may be disposed between the second electron transport portion ETU2′ and the second hole transport portion HTU2′. The third light emitting portion EU3′ may include a third light emitting layer EML3′, a third electron transport portion ETU3′, and a third hole transport portion HTU3′. The third light emitting layer EML3′ may be disposed between the third electron transport portion ETU3′ and the third hole transport portion HTU3′.

Each of the first to third hole transport portions HTU1′ to HTU3′ may include at least one of a hole injection layer and a hole transport layer, and may further include a hole buffer layer, an electron blocking layer, or the like as needed. The first to third hole transport portions HTU1′ to HTU3′ may have the same configuration or different configurations.

Each of the first to third electron transport portions ETU1′ to ETU3′ may include at least one of an electron injection layer and an electron transport layer, and may further include an electron buffer layer and a hole blocking layer as needed. The first to third electron transport portions ETU1′ to ETU3′ may have the same configuration or different configurations.

A first charge generation layer CGL1′ is disposed between the first light emitting portion EU1′ and the second light emitting portion EU2′. A second charge generation layer CGL2′ is disposed between the second light emitting portion EU2′ and the third light emitting portion EU3′.

In embodiments, the first to third light emitting layers EML1′ to EML3′ may respectively generate light of different colors. Light emitted from each of the first to third light emitting layers EML1′ to EML3′ may be mixed to be viewed as white light. For example, the first light emitting layer EML1′ may generate light of a blue color, the second light emitting layer EML2′ may generate light of a green color, and the third light emitting layer EML3′ may generate light of a red color.

In other embodiments, two or more of the first to third light emitting layers EML1′ to EML3′ may generate light of the same color. Unlike the example illustrated in FIG. 14 and FIG. 15, the light emitting structure EMS of FIG. 12 may include one light emitting portion in each of the first to third light emitting elements LD1 to LD3. In this case, the light emitting portions respectively included in the first to third light emitting elements LD1 to LD3 may be configured to respectively emit light of different colors. For example, the light emitting portion of the first light emitting element LD1 may emit red-colored light, the light emitting portion of the second light emitting element LD2 may emit green-colored light, and the light emitting portion of the third light emitting element LD3 may emit blue-colored light. In this case, unlike the example illustrated in FIG. 12, the light emitting portions of the first to third sub-pixels SP1 to SP3 are separated from each other, and each of the light emitting portions may be disposed in the opening OP of the pixel defining film PDL. In this case, at least some of the color filters CF1 to CF3 may be omitted.

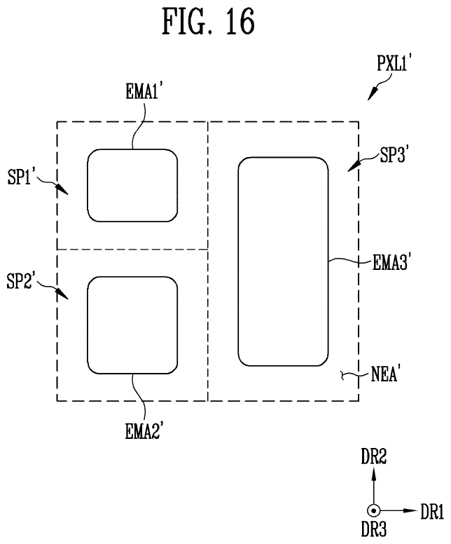

FIG. 16 illustrates a top plan view of one of pixels of FIG. 10 according to another embodiment.

Referring to FIG. 16, a first pixel PXL1′ may include first to third sub-pixels SP1′ to SP3′.

The first sub-pixel SP1′ may include a first light emitting area EMA1′ and a non-light emitting area NEA′ around the first light emitting area EMA1′. The second sub-pixel SP2′ may include a second light emitting area EMA2′ and a non-light emitting area NEA′ around the second light emitting area EMA2′. The third sub-pixel SP3′ may include a third light emitting area EMA3′ and a non-light emitting area NEA′ around the third light emitting area EMA3′.

The first sub-pixel SP1′ and the second sub-pixel SP2′ may be disposed in the second direction DR2. The third sub-pixel SP3′ may be disposed in the first direction DR1 with respect to each of the first and second sub-pixels SP1′ and SP2′.

The second sub-pixel SP2′ may have a larger area than the first sub-pixel SP1′, and the third sub-pixel SP3′ may have a larger area than the second sub-pixel SP2′. Accordingly, the second light emitting area EMA2′ may have a larger area than the first light emitting area EMA1′, and the third light emitting area EMA3′ may have a larger area than the second light emitting area EMA2′. However, embodiments are not limited thereto. For example, the first and second sub-pixels SP1′ and SP2′ may have substantially the same area, and the third sub-pixel SP3′ may have a larger area than each of the first and second sub-pixels SP1′ and SP2′. As such, the areas of the first to third sub-pixels SP1′ to SP3′ may be variously changed depending on embodiments.

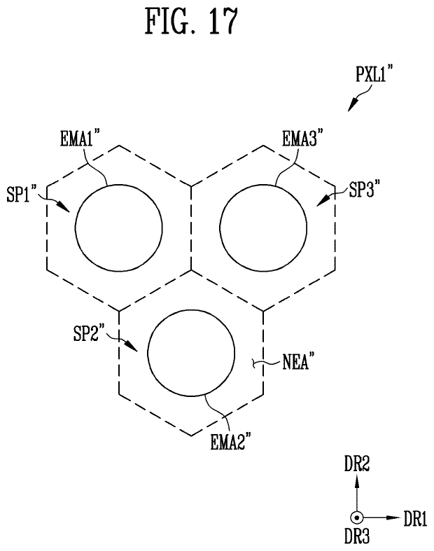

FIG. 17 illustrates a top plan view of one of pixels of FIG. 10 according to another embodiment.

Referring to FIG. 17, the first sub-pixel SP1″ may include a first light emitting area EMA1″ and a non-light emitting area NEA″ around the first light emitting area EMA1″. The second sub-pixel SP2″ may include a second light emitting area EMA2″ and a non-light emitting area NEA″ around the second light emitting area EMA2″. The third sub-pixel SP3″ may include a third light emitting area EMA3″ and a non-light emitting area NEA″ around the third light emitting area EMA3″.

The first to third sub-pixels SP1″ to SP3″ may have polygonal shapes when viewed in the third direction DR3. For example, the shapes of the first to third sub-pixels SP1″ to SP3″ may have hexagonal shapes as illustrated in FIG. 17.

The first to third light emitting areas EMA1″ to EMA3″ may have circular shapes when viewed in the third direction DR3. However, embodiments are not limited thereto. For example, each of the first to third light emitting areas EMA1″ to EMA3″ may have a polygonal shape.

The first and third sub-pixels SP1″ and SP3″ may be disposed in the first direction DR1. The second sub-pixel SP2″ may be disposed in a direction (or a diagonal direction) inclined by an acute angle with respect to the second direction DR2 with respect to the first sub-pixel SP1″.

The dispositions of the sub-pixels illustrated in FIGS. 11, 16, and 17 are merely examples, and embodiments are not limited thereto.

Each pixel may include two or more sub-pixels, the sub-pixels may be variously disposed, each of the sub-pixels may have various shapes, and each of its light emitting areas may also have various shapes.

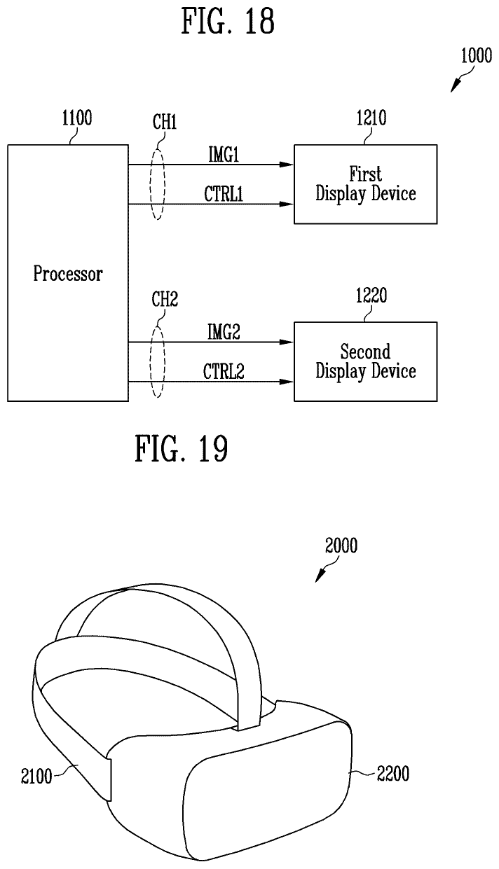

FIG. 18 illustrates a block diagram of an embodiment of a display system.

Referring to FIG. 18, the display system 1000 (or electronic device) may include a processor 1100 and one or more display devices 1210 and 1220.

The processor 1100 may perform various tasks and calculations. In embodiments, the processor 1100 may include an application processor, a graphics processor, a microprocessor, a central processing unit (CPU), and the like. The processor 1100 may be connected to and step other constituent elements of the display system 1000 through a bus system.

In FIG. 18, the display system 1000 is illustrated to include the first and second display devices 1210 and 1220. The processor 1100 may be connected to the first display device 1210 through a first channel CH1 and to the second display device 1220 through a second channel CH2.

Through the first channel CH1, the processor 1100 may transmit first image data IMG1 and a first control signal CTRL1 to the first display device 1210. The first display device 1210 may display an image based on the first image data IMG1 and the first control signal CTRL1. The first display device 1210 may be configured similarly to the display device 100 described with reference to FIG. 1. In this case, the first image data IMG1 and the first control signal CTRL1 may be provided as the input image data IMG and the control signal CTRL of FIG. 1, respectively. The first display device 1210 may be provided with the sub-pixels SP illustrated in FIG. 4 and FIG. 5.

Through the second channel CH2, the processor 1100 may transmit second image data IMG2 and a second control signal CTRL2 to the second display device 1220. The second display device 1220 may display an image based on the second image data IMG2 and the second control signal CTRL2. The second display device 1220 may be configured similarly to the display device 100 described with reference to FIG. 1. In this case, the second image data IMG2 and the second control signal CTRL2 may be provided as the input image data IMG and the control signal CTRL of FIG. 1, respectively. The second display device 1220 may be provided with the sub-pixels SP illustrated in FIG. 4 and FIG. 5.

The display system 1000 may include a computing system providing image display functions such as, for example, a portable computer, a mobile phone, a smart phone, a tablet personal computer (PC), a smart watch, a watch phone, a portable multimedia player (PMP), a navigation system, and a ultra mobile personal computer (UMPC). In some aspects, the display system 1000 may include at least one of a head-mounted display device (HMD), a virtual reality (VR) device, a mixed reality (MR) device, and an augmented reality (AR) device.

FIG. 19 illustrates a perspective view of an application example of the display system of FIG. 18.

Referring to FIG. 19, the display system 1000 of FIG. 18 may be applied to a head-mounted display device 2000. The head-mounted display device 2000 may be a wearable electronic device that may be worn on the user's head.

The head-mounted display device 2000 may include a head-mounted band 2100 and a display device accommodation case 2200. The head-mounted band 2100 may be connected to the display device accommodation case 2200. The head-mounted band 2100 may include a horizontal band and/or a vertical band for fixing the head-mounted display device 2000 to the user's head. The horizontal band may be configured to surround the side portion of the user's head, and the vertical band may be configured to surround the upper portion of the user's head. However, embodiments are not limited thereto. For example, the head-mounted band 2100 may be implemented in the form of a spectacle frame, a helmet, or the like.

The display device accommodation case 2200 may accommodate the first and second display devices 1210 and 1220 of FIG. 18. The display device accommodation case 2200 may further accommodate the processor 1100 of FIG. 12.

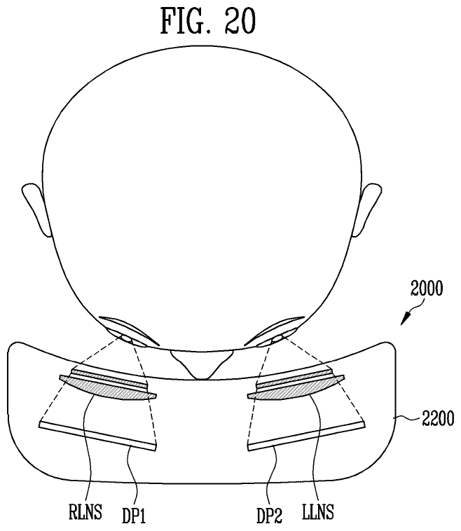

FIG. 20 illustrates a head-mounted display device worn on a user of FIG. 19.

Referring to FIG. 20, a first display panel DP1 of the first display device 1210 and a second display panel DP2 of the second display device 1220 are disposed in the head mounted display device 2000. The head-mounted display device 2000 may further include one or more lenses LLNS and RLNS.

In the display device accommodation case 2200, the right eye lens RLNS may be disposed between the first display panel DP1 and the right eye of the user. In the display device accommodation case 2200, the left eye lens LLNS may be disposed between the second display panel DP2 and the left eye of the user.

An image outputted from the first display panel DP1 may be illustrated to the right eye of the user through the right eye lens RLNS. The right eye lens RLNS may refract light from the first display panel DP1 to be directed to the right eye of the user. The right eye lens RLNS may perform an optical function to adjust the viewing distance between the first display panel DP1 and the right eye of the user.

An image outputted from the second display panel DP2 may be illustrated to the left of the user through the left eye lens LLNS. The left eye lens LLNS may refract light from the second display panel DP2 to be directed to the left eye of the user. The left eye lens LLNS may perform an optical function to adjust the viewing distance between the second display panel DP2 and the left eye of the user.

In embodiments, each of the right eye lens RLNS and the left eye lens LLNS may include an optical lens having a cross-section of a pancake shape. In the embodiments, each of the right eye lens RLNS and the left eye lens LLNS may include a multi-channel lens including sub-areas with different optical characteristics. In this case, each display panel outputs images corresponding to the sub-areas of the multi-channel lens, and the output images may pass through the sub-areas and be viewed by the user.

Although certain embodiments and implementations have been described herein, other embodiments and modifications will be apparent from this description. Accordingly, the inventive concept is not limited to the embodiments, but rather to the broader scope of the presented claims and various obvious modifications and equivalent arrangements.

What is claimed is:

1. A sub-pixel comprising:
a first transistor comprising a first electrode connected to a first node, a second electrode connected to a second node, and a gate electrode connected to a third node;
a second transistor that is connected between a data line and the third node, wherein a gate electrode of the second transistor is connected to a first sub-gate line;
a first capacitor connected between the first node and the third node; and
a second capacitor connected between the second node and the third node,
wherein the first capacitor and the second capacitor are formed as different types of capacitors.

2. The sub-pixel of claim 1, wherein:
the first capacitor is a metal-oxide-semiconductor (MOS) capacitor, and the second capacitor is a metal-oxide-metal (MOM) capacitor.

3. The sub-pixel of claim 1, wherein:
the first capacitor has a higher capacity than the second capacitor.

4. The sub-pixel of claim 1, wherein:
the first capacitor is formed on the same layer as the first transistor, and
the second capacitor is formed on a different layer from the first transistor.

5. The sub-pixel of claim 4, wherein:
the second capacitor comprises a first electrode and a second electrode, and the first electrode is formed on the same layer as the second electrode.

6. The sub-pixel of claim 1, wherein:
a mounting area of the first capacitor is larger than a mounting area of the first transistor or a mounting area of the second transistor.

7. The sub-pixel of claim 1, further comprising:
a third transistor that is connected between a first power voltage node to which a first power voltage is inputted and the first node, wherein a gate electrode of the third transistor is connected to a light emitting control line;
a light emitting element connected between a second power voltage node to which a second power voltage is inputted and the second node; and
a fourth transistor that is connected between the second node and an initialization voltage node to which an initialization voltage is supplied, wherein a gate electrode of the fourth transistor is connected to a second sub-gate line.

8. The sub-pixel of claim 7, wherein:
the initialization voltage is the same voltage as the second power voltage, and the initialization voltage node is electrically connected to the second power voltage node.

9. The sub-pixel of claim 7, wherein:
the initialization voltage is set such that the light emitting element is turned off when the initialization voltage is supplied to the second node.

10. The sub-pixel of claim 7, wherein:
each of the first transistor, the second transistor, the third transistor, and the fourth transistor is a metal-oxide-semiconductor field-effect transistor (MOSFET) including a body electrode.

11. The sub-pixel of claim 10, wherein:
the first power voltage is inputted to the body electrodes of the first transistor, the second transistor, the third transistor, and the fourth transistor.

12. The sub-pixel of claim 7, wherein:
the sub-pixel is driven in a first period, a second period, and a third period,
the second transistor is turned on during the first period and the second period,
the fourth transistor is turned on during the first period to the third period, and
the third transistor is turned off during the second period.

13. The sub-pixel of claim 12, wherein:
a data signal is supplied to the data line during at least a portion of the second period.

14. A display device comprising:
sub-pixels connected to gate lines, light emitting control lines, and data lines;
a gate driver driving the gate lines and the light emitting control lines; and
a data driver driving the data lines,
wherein a sub-pixel of the sub-pixels includes:
a first transistor comprising a first electrode connected to a first node, a second electrode connected to a second node, and a gate electrode connected to a third node;
a second transistor that is connected between a data line, which is one of the data lines, and the third node, wherein a gate electrode of the second transistor is connected to a first sub-gate line, which is one of the gate lines;
a first capacitor connected between the first node and the third node; and
a second capacitor connected between the second node and the third node, and
the first capacitor and the second capacitor are formed as different types of capacitors.

15. The display device of claim 14, wherein:
the first capacitor is a metal-oxide-semiconductor (MOS) capacitor, and the second capacitor is a metal-oxide-metal (MOM) capacitor.

16. The display device of claim 14, wherein:
the first capacitor has a higher capacity than the second capacitor.

17. The display device of claim 14, wherein:
the first capacitor is formed on the same layer as the first transistor, and
the second capacitor is formed on a different layer from the first transistor.

18. The display device of claim 17, wherein:
the second capacitor comprises a first electrode and a second electrode, and the first electrode is formed on the same layer as the second electrode.

19. The display device of claim 14, wherein:
a mounting area of the first capacitor is larger than a mounting area of the first transistor or a mounting area of the second transistor.

20. The display device of claim 14, wherein the sub-pixel further comprises:
a third transistor that is connected between a first power voltage node to which a first power voltage is inputted and the first node, wherein a gate electrode of the third transistor is connected to one of the light emitting control lines;
a light emitting element connected between a second power voltage node to which a second power voltage is inputted and the second node; and
a fourth transistor that is connected between the second node and an initialization voltage node to which an initialization voltage is supplied, wherein a gate electrode of the fourth transistor is connected to a second sub-gate line that is one of the gate lines.

21. The display device of claim 20, wherein:
the initialization voltage is the same voltage as the second power voltage, and the initialization voltage node is electrically connected to the second power voltage node.

22. The display device of claim 20, wherein:
each of the first transistor, the second transistor, the third transistor, and the fourth transistor includes a body electrode, and the first power voltage is inputted to the body electrodes of the first transistor, the second transistor, the third transistor, and the fourth transistor.

23. The display device of claim 20, wherein:
the sub-pixel is driven in a first period, a second period, and a third period,
the gate driver supplies a first scan signal to the first sub-gate line such that the second transistor is turned on during the first period and the second period,
the gate driver supplies a second scan signal to the second sub-gate line such that the fourth transistor is turned on during the first period to the third period,
the gate driver supplies a light emitting control signal to the light emitting control line such that the third transistor is turned off during the second period, and
the data driver supplies a data signal to the data line during at least a portion of the second period.

24. An electronic device, comprising:
a processor to provide input image data;
a display device to display an image based on the input image data; and
wherein the display device comprising:
sub-pixels connected to gate lines, light emitting control lines, and data lines;
a gate driver driving the gate lines and the light emitting control lines; and
a data driver driving the data lines,
wherein a sub-pixel of the sub-pixels includes:
a first transistor comprising a first electrode connected to a first node, a second electrode connected to a second node, and a gate electrode connected to a third node;
a second transistor that is connected between a data line, which is one of the data lines, and the third node, wherein a gate electrode of the second transistor is connected to a first sub-gate line, which is one of the gate lines;
a first capacitor connected between the first node and the third node; and
a second capacitor connected between the second node and the third node, and
the first capacitor and the second capacitor are formed as different types of capacitors.
